(19) United States
(12) Patent Application Publication
(10) Pub. No.: US 2011/0006360 A1
(43) Pub. Date: Jan. 13, 2011

(54) SEMICONDUCTOR DEVICE HAVING 3D-PILLAR VERTICAL TRANSISTOR AND MANUFACTURING METHOD THEREOF

(75) Inventor: Yoshinori Ikebuchi, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc., Tokyo (JP)

(21) Appl. No.: 12/824,858

(22) Filed: Jun. 28, 2010

(30) Foreign Application Priority Data
Jul. 10, 2009 (JP) 2009-163473

(51) Int. Cl. H01L 29/78

(52) U.S. Cl. 257/329; 257/E29.262

(57) ABSTRACT

A semiconductor device includes: a semiconductor substrate; a silicon pillar having a side surface perpendicular to a main surface of the semiconductor substrate; a gate dielectric film that covers a side surface of the silicon pillar; a gate electrode that has an inner-circumference side surface and an outer-circumference side surface which are perpendicular to the main surface of the semiconductor substrate, and covers a side surface of the silicon pillar such that the inner-circumference side surface and the side surface of the silicon pillar face each other via the gate dielectric film; a gate-electrode protection film that covers at least a part of the outer-circumference side surface of the gate electrode; an interlayer dielectric film provided above the gate electrode and the gate-electrode protection film; and a gate contact plug that is embedded in a contact hole provided on the interlayer dielectric film and is in contact with the gate electrode and the gate-electrode protection film.

### BACKGROUND OF THE INVENTION

1. Field of the Invention

The present invention relates to a semiconductor device and a manufacturing method thereof, and more particularly relates to a semiconductor device using a 3D-pillar vertical transistor and a manufacturing method thereof.

2. Description of Related Art

In recent years, from viewpoints of chip size reduction and performance improvement, a three-dimensional vertical all-around gate transistor (hereinafter, “3D-pillar vertical transistor”) in which a current flows in a direction perpendicular to a main surface of a substrate has been proposed as a transistor that constitutes a semiconductor device (see Japanese Patent Application Laid-open Nos. 2007-123415 and 2008-288391).

According to a 3D-pillar vertical transistor disclosed in Japanese Patent Laid-open No. 2008-288391, plural silicon pillars are provided on a surface of a silicon substrate, and a part of the silicon pillars are used for channels. An impurity diffusion layer that serves as a source and another impurity diffusion layer that serves as a drain are formed on an upper part and a lower part, respectively, of each silicon pillar used for a channel.

Gate electrodes are provided to cover a sidewall of each silicon pillar. Specifically, a gate electrode material such as polycrystalline silicon is formed in a state that a nitride film mask for a silicon pillar formation remains on an upper part of the silicon pillar, and a formed film is etched back by anisotropic dry etching. Consequently, a gate electrode remains only on the sidewall of the silicon pillar. An impurity diffusion layer at the upper part of the silicon pillar (hereinafter, “upper diffusion layer”) is formed within a hole formed by removing the nitride film mask after the gate electrode is formed. Informing the upper diffusion layer, a sidewall nitride film is provided on an internal wall surface of the hole. Accordingly, because the sidewall nitride film is present between the upper diffusion layer and the gate electrode, a contact between the upper diffusion layer and the gate electrode is prevented.

However, when the upper diffusion layer and the gate electrode are separated from each other by a thin sidewall nitride film, a relatively large floating capacitance is formed between the upper diffusion layer and the gate electrode. This floating capacitance increases power consumption and reduces an operation speed. Therefore, it is desirable to reduce the floating capacitance as far as possible. Accordingly, there has been examined a method of reducing a floating capacitance between an upper diffusion layer and a gate electrode by lowering an upper surface position of the gate electrode by performing etching back of a gate electrode material for a relatively long time.

However, because etching back of the gate electrode material also proceeds in a lateral direction, performing the etching back for a long time decreases the film thickness of the gate electrode that covers sidewalls of the silicon pillars. Therefore, at the time of opening a gate contact hole to manufacture a contact plug to connect between the gate electrode and a wiring of an upper layer, there is a risk that the gate contact hole goes beyond the gate electrode having a very small thickness, and the gate contact plug is short-circuited with the silicon substrate (particularly, an impurity diffusion layer at a lower part of the silicon pillars).

### SUMMARY

In one embodiment, there is provided a semiconductor device comprising: a semiconductor substrate; at least one silicon pillar having a side surface perpendicular to a main surface of the semiconductor substrate; a gate dielectric film that covers a side surface of the silicon pillar; a gate electrode that has an inner-circumference side surface and an outer-circumference side surface which are perpendicular to a main surface of the semiconductor substrate, and covers a side surface of the silicon pillar such that the inner-circumference side surface and the side surface of the silicon pillar face each other via the gate dielectric film; a gate-electrode protection film that covers at least a part of the outer-circumference side surface of the gate electrode; an interlayer dielectric film provided above the gate electrode and the gate-electrode protection film; and a gate contact plug that is embedded in a contact hole provided on the interlayer dielectric film and is in contact with the gate electrode and the gate-electrode protection film.

In another embodiment, there is provided a manufacturing method of a semiconductor device comprising: forming a film of a gate electrode material on a main surface of a silicon substrate having at least one silicon pillar; leaving the gate electrode material on a side surface of the silicon pillar by etching back the gate electrode material; forming a gate-electrode protection film that covers the gate electrode material; leaving the gate-electrode protection film on a side surface of the gate electrode material by etching back the gate-electrode protection film; lowering an upper surface position of the gate electrode material by etching back the gate electrode material after the etch back of the gate-electrode protection film; forming an interlayer oxide film that covers the gate electrode material and the gate-electrode protection film; forming a contact hole in the interlayer oxide film above the gate electrode material and the gate-electrode protection film; and forming a contact plug within the contact hole.

According to the present invention, because a positional deviation margin between the gate contact plug and the gate electrode increases, the possibility that the gate contact plug is short-circuited with the silicon substrate can be reduced.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a schematic cross-sectional view showing a configuration of a 3D-pillar vertical transistor included in a peripheral circuit of a semiconductor device according to an embodiment of the present invention along a line A-A′ in FIG. 1B;

FIG. 1B is a schematic plan view showing a configuration of a 3D-pillar vertical transistor included in a peripheral circuit of the semiconductor device according to the embodiment of the present invention;

FIG. 2 is a schematic cross-sectional view showing a configuration of plural 3D-pillar vertical transistors included in a memory cell region of the semiconductor device according to the embodiment of the present invention along a line B-B′ in FIG. 4A;

FIG. 3 is a schematic cross-sectional view showing a configuration of plural 3D-pillar vertical transistors included in a memory cell region of the semiconductor device according to the embodiment of the present invention along a line C-C′ in FIG. 4A;

FIG. 4A is a schematic plan view showing a configuration of plural 3D-pillar vertical transistors included in a memory cell region of the semiconductor device according to the embodiment of the present invention (part 1);

FIG. 4B is a schematic plan view showing a configuration of plural 3D-pillar vertical transistors included in a memory cell region of the semiconductor device according to the embodiment of the present invention (part 2);

FIGS. 5, 7, 9, 11, 13, 15, 17, 19, 21, 23, 25, 27, 29, 31, 33, 35, 37, 39, and 41 are process diagrams for explaining the manufacturing method of a 3D-pillar vertical transistor included in a peripheral circuit of the semiconductor device according to the embodiment of the present invention and shows a cross-sectional view corresponding to the cross-sectional view along the line A-A′ in FIG. 1B;

FIGS. 6A, 8A, 10A, 12A, 14A, 16A, 18A, 20A, 22A, 24A, 26A, 28A, 30A, 32A, 34A, 36A, 38A, 40A, and 42A are process diagrams for explaining the manufacturing method of plural 3D-pillar vertical transistors included in a memory cell region of the semiconductor device according to the embodiment of the present invention and shows a cross-sectional view corresponding to the cross-sectional view along the line B-B′ in FIG. 4A;

FIGS. 6B, 8B, 10B, 12B, 14B, 16B, 18B, 20B, 22B, 24B, 26B, 28B, 30B, 32B, 34B, 36B, 38B, 40B, and 42B are process diagrams for explaining the manufacturing method of plural 3D-pillar vertical transistors included in a memory cell region of the semiconductor device according to the embodiment of the present invention and shows a cross-sectional view corresponding to the cross-sectional view along the line C-C′ in FIG. 4A;

FIG. 43 is a process diagram for explaining the manufacturing method of a 3D-pillar vertical transistor included in a peripheral circuit of the semiconductor device according to the modification of the embodiment of the present invention and corresponds to FIG. 23;

FIG. 44A is a process diagram for explaining the manufacturing method of plural 3D-pillar vertical transistors included in a memory cell region of the semiconductor device according to the modification of the embodiment of the present invention and corresponds to FIG. 24A;

FIG. 44B is a process diagram for explaining the manufacturing method of plural 3D-pillar vertical transistors included in a memory cell region of the semiconductor device according to the modification of the embodiment of the present invention and corresponds to FIG. 24B;

FIG. 45 is a process diagram for explaining the manufacturing method of a 3D-pillar vertical transistor included in a peripheral circuit of the semiconductor device according to the modification of the embodiment of the present invention and corresponds to FIG. 27;

FIG. 46A is a process diagram for explaining the manufacturing method of plural 3D-pillar vertical transistors included in a memory cell region of the semiconductor device according to the modification of the embodiment of the present invention and corresponds to FIG. 28A;

FIG. 46B is a process diagram for explaining the manufacturing method of plural 3D-pillar vertical transistors included in a memory cell region of the semiconductor device according to the modification of the embodiment of the present invention and corresponds to FIG. 28B;

FIG. 47 is a process diagram for explaining the manufacturing method of a 3D-pillar vertical transistor included in a peripheral circuit of the semiconductor device according to the modification of the embodiment of the present invention and corresponds to FIG. 33;

FIG. 48A is a process diagram for explaining the manufacturing method of plural 3D-pillar vertical transistors included in a memory cell region of the semiconductor device according to the modification of the embodiment of the present invention and corresponds to FIG. 34A; and

FIG. 48B is a process diagram for explaining the manufacturing method of plural 3D-pillar vertical transistors included in a memory cell region of the semiconductor device according to the modification of the embodiment of the present invention and corresponds to FIG. 34B.

### DETAILED DESCRIPTION OF THE PREFERRED EMBODIMENTS

Preferred embodiments of the present invention will be explained below in detail with reference to the accompanying drawings. In the following embodiments, a semiconductor device 10 as a DRAM (Dynamic Random Access Memory) is explained as an example.

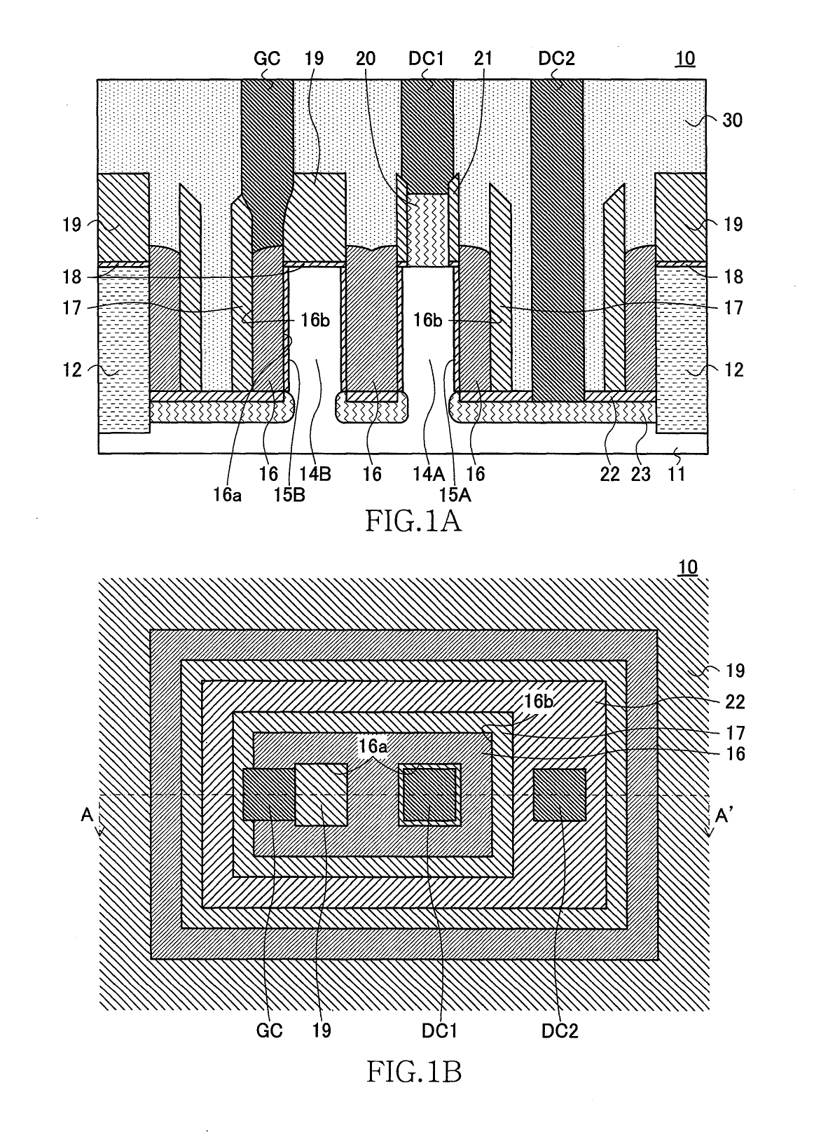

FIGS. 1A and 1B show a configuration of a 3D-pillar vertical transistor included in a peripheral circuit of the semiconductor device 10 according to an embodiment of the present invention; where FIG. 1A is a schematic cross-sectional view and FIG. 1B is a schematic plan view. FIG. 1A is a cross-sectional view along a line A-A′ in FIG. 1B.

As shown in FIGS. 1A and 1B, the semiconductor device 10 according to the embodiment includes a STI (Shallow Trench Isolation) 12 formed on a main surface of a silicon substrate 11, and a first silicon pillar 14A and a second silicon pillar 14B formed within a region (an active region) surrounded by the STI 12.

The first and second silicon pillars 14A and 14B stand together adjacently, and have side surfaces perpendicular to the main surface of the silicon substrate 11. A first gate dielectric film 15A and a second gate dielectric film 15B are formed by thermal oxidation on the side surfaces of the first and second silicon pillars 14A and 14B, respectively.

A gate electrode 16 made of a polycrystalline silicon film is formed to surround an outer circumference of the first and second gate dielectric films 15A and 15B. An interval between the first and second silicon pillars 14A and 14B is set smaller than two times of the film thickness of the gate electrode 16. Therefore, the gate electrode 16 at an outer circumference of the first silicon pillar 14A and the gate electrode 16 at an outer circumference of the second silicon pillar 14B are integrated together, thereby constituting one gate electrode 16.

The gate electrode 16 has an inner-circumference side surface 16a and an outer-circumference side surface 16b perpendicular to the main surface of the silicon substrate 11. The inner-circumference side surface 16a faces side surfaces of the first and second silicon pillars 14A and 14B via the gate dielectric films 15A and 15B. The outer-circumference side surface 16b is covered with a gate-electrode protection film 17 made of a silicon nitride film.

A substrate protection film (a silicon oxide film) 18 and a cap insulation film (a silicon nitride film) 19 used for masks at the time of forming silicon pillars remain without being removed at an upper part of the second silicon pillar 14B. The substrate protection film 18 and the cap insulation film 19 are similarly left at an upper part of the STI 12.

On the other hand, the substrate protection film 18 and the cap insulation film 19 are removed at an upper part of the first silicon pillar 14A, and a first diffusion layer 20 is formed instead.

A second diffusion layer 23 is formed at lower parts of the first and second silicon pillars 14A and 14B. The second diffusion layer 23 is formed in a flat region of the silicon substrate 11 in which a silicon pillar is not formed, not in a region immediately beneath the first and second silicon pillars 14A and 14B.

The semiconductor device 10 further includes an interlayer dielectric film 30 made of a silicon oxide film that covers the main surface of the silicon substrate 11. The film thickness of the interlayer dielectric film 30 is set at a film thickness exceeding heights of the first diffusion layer 20 and the cap insulation film 19.

Three through-hole conductors DC1 (a first diffusion-layer contact plug), DC2 (a second diffusion-layer contact plug), and GC (a gate contact plug) are formed in the interlayer dielectric film 30. A lower part of the first diffusion-layer contact plug DC1 is in contact with an upper surface of the first diffusion layer 20. A lower part of the second diffusion-layer contact plug DC2 is in contact with the second diffusion layer 23. A lower part of the gate contact plug GC is in contact with an upper surface of the gate electrode 16 and an upper surface of the gate-electrode protection film 17. The gate contact plug GC is in contact with a part of a portion positioned at a peripheral boarder of the second silicon pillar 14B (a portion at an opposite side of the first silicon pillar 14A sandwiching the second silicon pillar 14B) of the upper surface of the gate electrode 16. Upper parts of the contact plugs DC1, DC2, and GC, respectively, are connected to a wiring layer (not shown) formed on the interlayer dielectric film 30.

In the semiconductor device 10 having the above configuration, the first silicon pillar 14A becomes a channel of a transistor. The first diffusion layer 20 functions as one of a source and a drain and the second diffusion layer 23 functions as the other one of the source and the drain. A source, a drain, and a gate of a transistor are extracted to the wiring layer by the contact plugs DC1, DC2, and GC, respectively.

An ON/OFF control of a transistor is performed by an electric field given to the gate electrode 16 through the gate contact plug GC. A channel is formed within the first silicon pillar 14A positioned between the first diffusion layer 20 and the second diffusion layer 23.

The second silicon pillar 14B is a dummy pillar provided to make the gate contact plug GC, and does not function as a transistor. By providing the second silicon pillar 14B, a gate electrode configuration not requiring photolithography to form a flat portion of the gate electrode 16 is achieved.

According to the configuration of the semiconductor device 10 explained above, an upper surface position of the gate electrode 16 can be sufficiently lowered. That is, as described above, because the outer-circumference side surface 16b of the gate electrode 16 is covered with the gate-electrode protection film 17 made of a silicon nitride film, the etching back does not proceed to a lateral direction at the time of etching back the gate electrode 16 made of polycrystalline silicon to lower the upper surface position. Consequently, even when the upper surface position of the gate electrode 16 is sufficiently lowered to reduce a floating capacitance between the first diffusion layer 20 and the gate electrode 16, the film thickness of the gate electrode 16 can be held. Therefore, the possibility that the gate contact plug GC is short-circuited with the second diffusion layer 23 can be reduced. From a reverse viewpoint, etching back of the gate electrode 16 can be performed without being concerned about too much reduction of the film thickness of the gate electrode 16. Because the upper surface position of the gate electrode 16 can be sufficiently lowered, a floating capacitance between the first diffusion layer 20 and the gate electrode 16 can be sufficiently reduced.

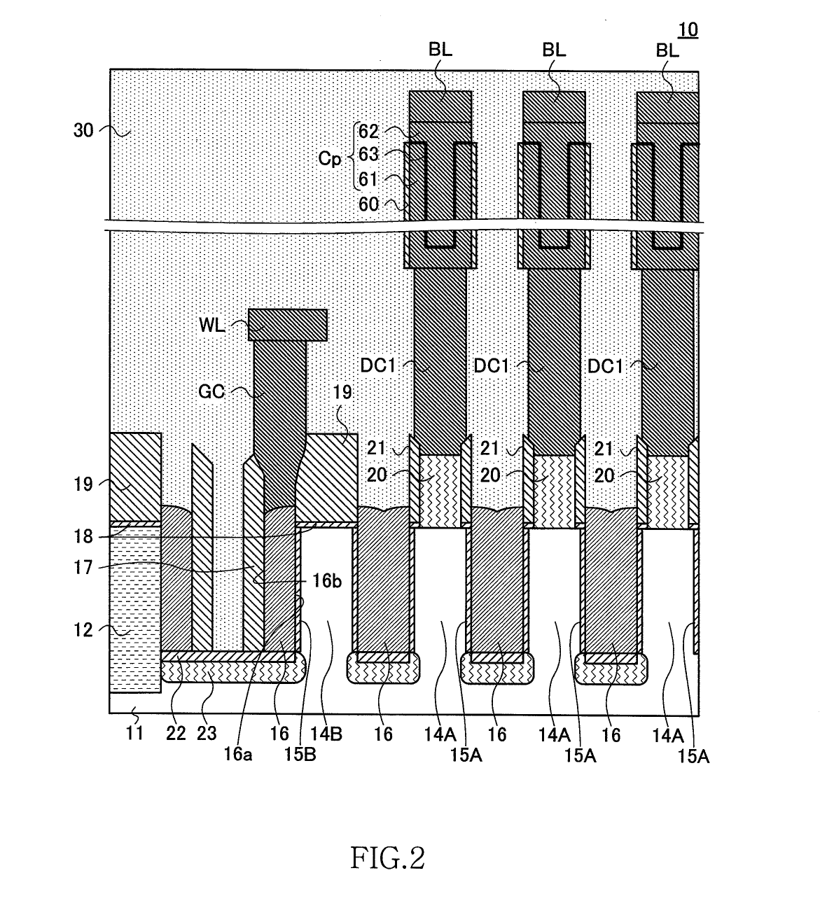

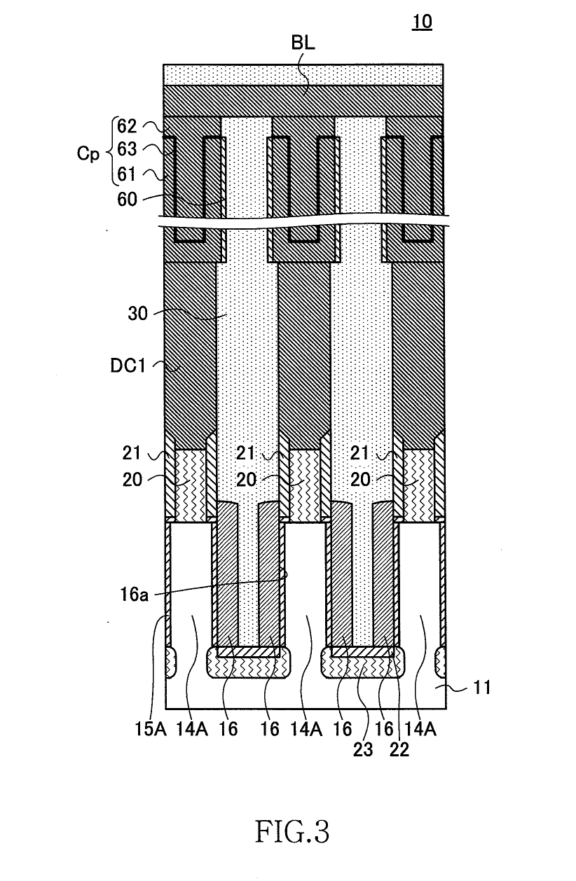

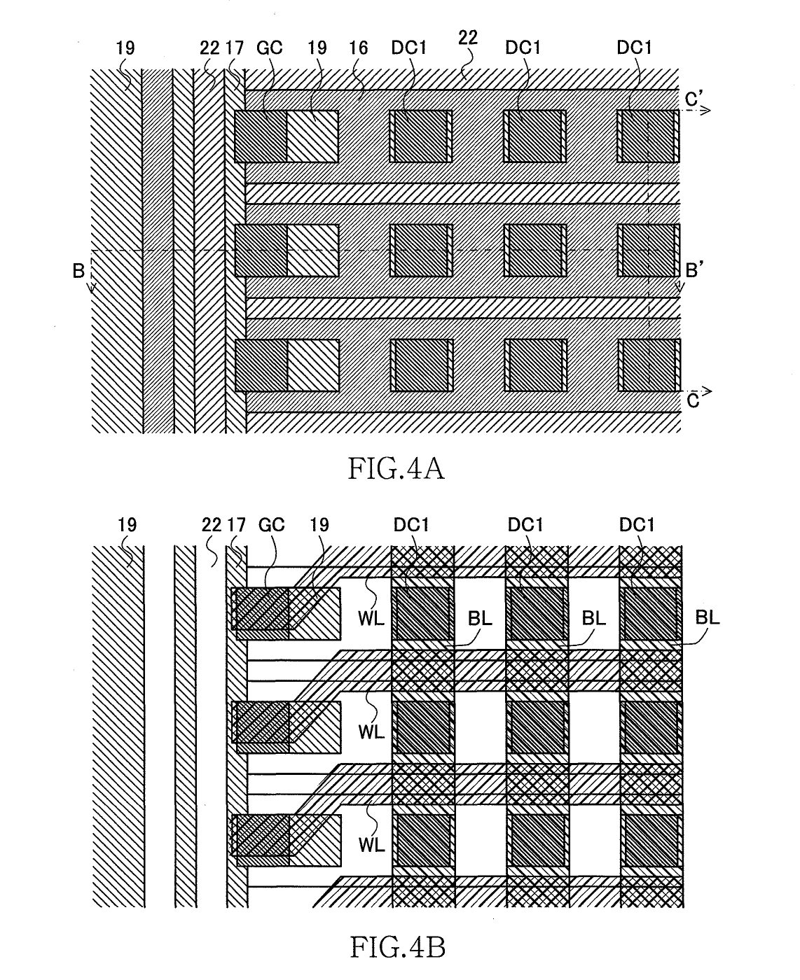

FIG. 2 to FIG. 4 show a configuration of plural 3D-pillar vertical transistors included in a memory cell region of the semiconductor device 10 according to the embodiment of the present invention; where FIGS. 2 and 3 are schematic cross-sectional views and FIGS. 4A and 4B are schematic plan views. FIGS. 2 and 3 are a cross-sectional view along a line B-B′ in FIG. 4A, and a cross-sectional view along a line C-C′ in FIG. 4A, respectively.

In a memory cell portion, the basic configuration of a 3D-pillar vertical transistor is similar to that of a peripheral circuit portion. That is, the first silicon pillar 14A constituting a 3D-pillar vertical transistor and the second silicon pillar 14B as a dummy pillar are provided. Side surfaces of these silicon pillars are covered with the gate dielectric films 15A and 15B, respectively. The gate electrode 16 covers the side surfaces of the first and second silicon pillars 14A and 14B via the gate dielectric films 15A and 15B. The gate electrode 16 has the inner-circumference side surface 16a and the outer-circumference side surface 16b perpendicular to the main surface of the silicon substrate 11. The inner-circumference side surface 16a faces the side surfaces of the first and second silicon pillars 14A and 14B. On the other hand, the outer-circumference side surface 16b is covered with the gate-electrode protection film 17 made of a silicon nitride film. The gate-electrode protection film 17 can reduce the possibility that the gate contact plug GC is short-circuited with the second diffusion layer 23. This mechanism is similar to that explained regarding the peripheral circuit.

A largest difference of a configuration of the peripheral circuit and the memory circuit is that plural silicon pillars are arranged in a matrix shape as shown in FIGS. 4A and 4B. The second silicon pillars 14B are arranged in a left end column of a matrix, and the first silicon pillars 14A are arranged in other columns.

The gate electrodes 16 formed on side surfaces of silicon pillars aligned in a row direction (a lateral direction in FIGS. 4A and 4B) (one second silicon pillar 14B, and plural first silicon pillars 14A) are integrated together to constitute one gate electrode 16, as shown in FIG. 2 and FIG. 4A. This gate electrode 16 is connected to a word line WL via the gate contact plug GC in each row, as shown in FIG. 2 and FIG. 4B. Each second silicon pillar 14B constitutes a cell transistor, and is connected to a cell capacitor Cp via the first diffusion-layer contact plug DC1, as shown in FIGS. 2 and 3.

As shown in FIGS. 2 and 3, the cell capacitor Cp is configured by a cylindrical lower electrode 61 connected to the first diffusion-layer contact plug DC1, a circular-cylindrical upper electrode 62 connected to a bit line BL, and a capacitance dielectric film 63 provided between the lower electrode 61 and the upper electrode 62. The bit line BL is extended to a direction orthogonal with the word line WL, and connects between plural cell capacitors Cp arranged in a column direction, as shown in FIG. 3 and FIG. 4B.

Based on the above configuration, when the word line WL becomes a high level, a cell transistor arranged in a corresponding row is turned on, and the bit line BL is connected to the second diffusion layer 23 as a common node via the cell capacitor Cp. Accordingly, data can be read and written in the cell capacitor Cp via the bit line BL.

A manufacturing method of the semiconductor device 10 according to the embodiment is explained next in detail.

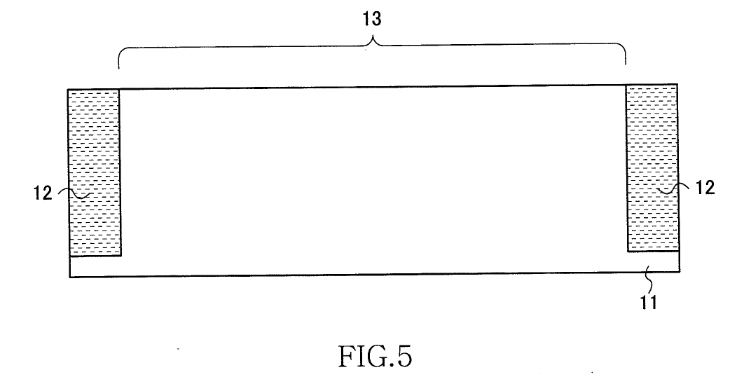

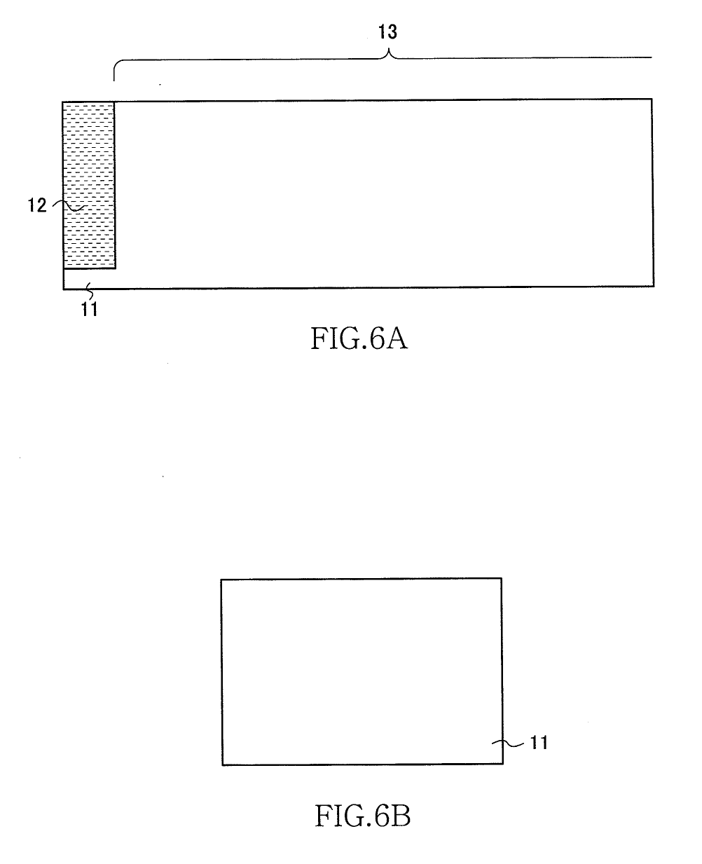

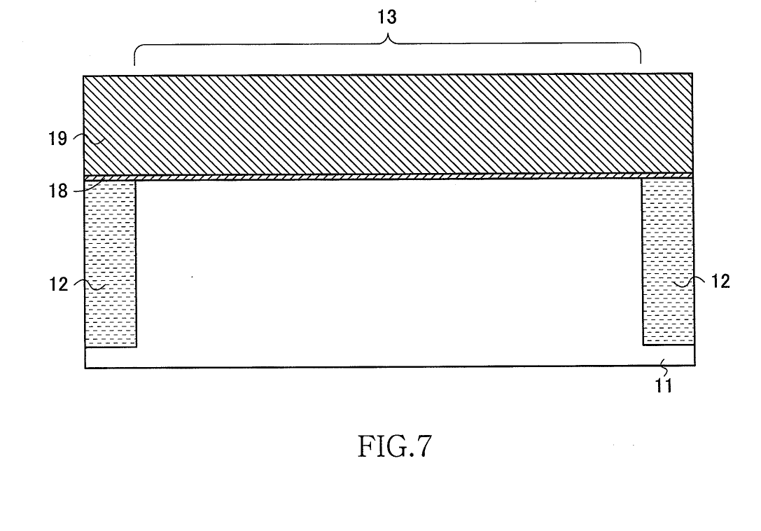

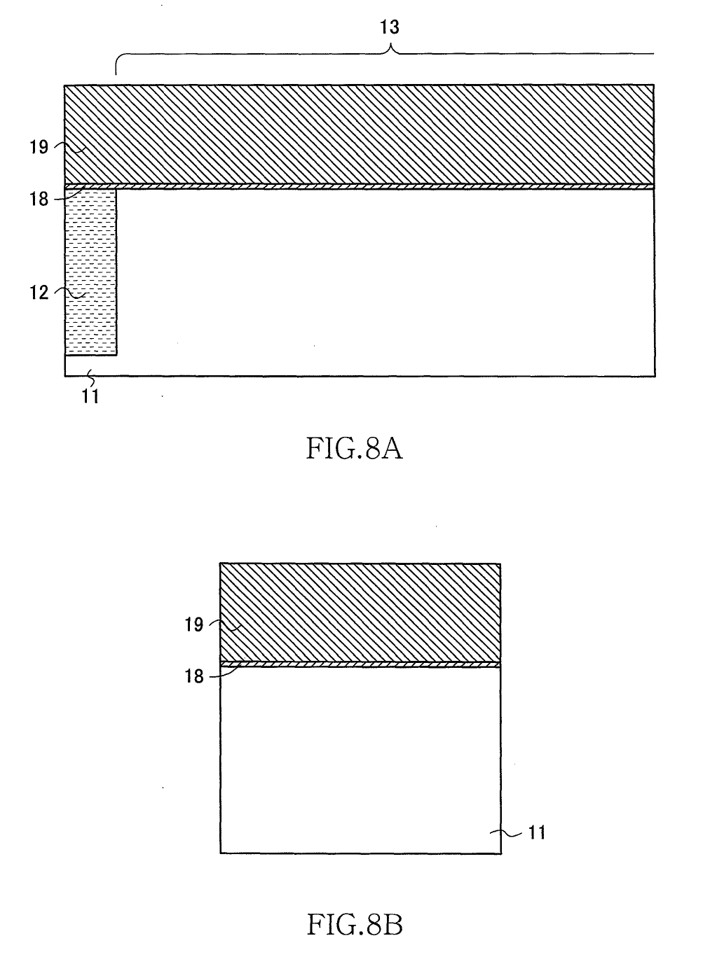

FIG. 5 to FIG. 42 are process diagrams for explaining the manufacturing method of the semiconductor device 10 according to the embodiment. The manufacturing method explained here is a method of simultaneously forming a 3D-pillar vertical transistor within a peripheral circuit and a 3D-pillar vertical transistor within a memory cell region. The method is explained with reference to the drawings of both transistors. That is, among FIG. 5 to FIG. 42, the drawings of odd numbers such as FIG. 5 and FIG. 7 show a manufacturing process of a 3D-pillar vertical transistor within a peripheral circuit, and show a cross section corresponding to the cross-sectional view along the line A-A′ in FIG. 1B. Meanwhile, the drawings of even numbers such as FIG. 6 and FIG. 8 show a manufacturing process of plural 3D-pillar vertical transistors included in a memory region, and A and B of each of the drawing show cross sections corresponding to the cross-sectional view along the line B-B′ and the cross-sectional view along the line C-C′, respectively in FIG. 4A.

In the manufacturing of the semiconductor device 10, the silicon substrate 11 is prepared first. By forming the STI 12 on the silicon substrate 11, an active region 13 surrounded by the STI 12 is formed (FIG. 5 and FIG. 6A). Although more active regions are formed on the silicon substrate 11 in practice, the drawings show only a part of the active regions. Although not particularly limited thereto, the active region 13 according to the embodiment has a rectangular shape.

In forming the STI 12, a trench having a depth of about 220 nm is formed by dry etching on the main surface of the silicon substrate 11. A silicon oxide film having a small thickness is formed by thermal oxidation at about 1000° C. on the entire surface of the substrate including an internal wall of the trench. Thereafter, a silicon oxide film having a thickness of 400 nm to 500 nm is deposited by an HDP (High Density Plasma) method on the entire surface of the substrate including inside of the trench. Thereafter, the silicon oxide film not necessary on the silicon substrate 11 is removed by CMP (Chemical Mechanical Polishing), and the silicon oxide film is left in only inside of the trench, thereby forming the STI 12.

Next, the first and second silicon pillars 14A and 14B are formed simultaneously within the active region 13. In forming the silicon pillars 14A and 14B, the substrate protection film 18 made of a silicon oxide film is formed on the entire surface of the silicon substrate 11. The insulation film 19 made of a silicon nitride film is formed on the substrate protection film 18 (FIGS. 7, 8A, and 8B). Although not particularly limited thereto, the substrate protection film 18 can be formed by thermal oxidation, and the insulation film 19 can be formed by a CVD (Chemical Vapor Deposition) method. Preferably, the film thickness of the substrate protection film 18 is about 5 nm, and the film thickness of the cap insulation film 19 is about 120 nm.

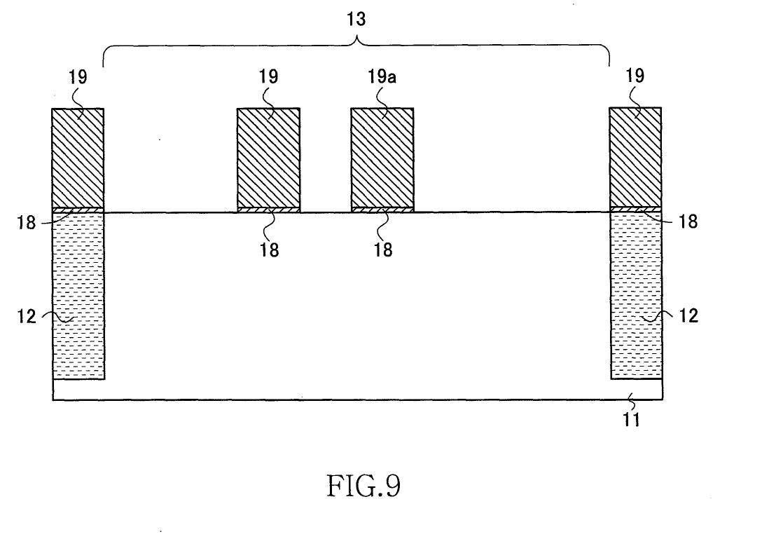

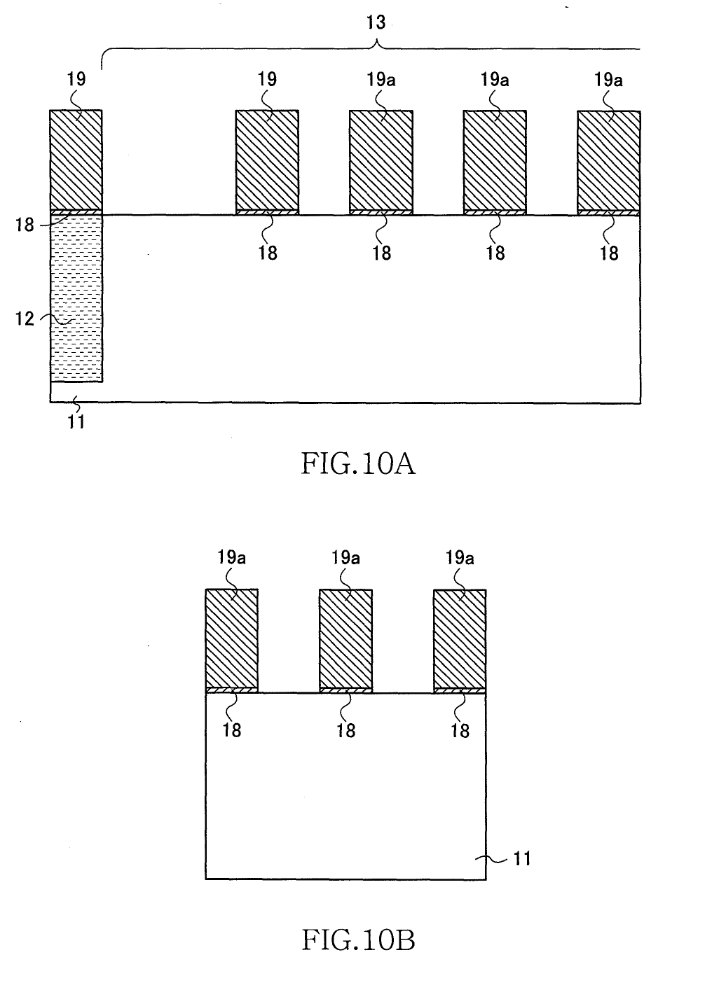

Thereafter, a mask pattern including patterns corresponding to formation positions of the first and second silicon pillars 14A and 14B and the STI 12 is formed by patterning the insulation film 19 (FIGS. 9, 10A, and 10B). In the following explanations, the insulation film 19 corresponding to a formation position of the silicon pillar 14A is called “insulation film 19a (or cap insulation film 19a)” by particularly distinguishing this film from other films. In performing this patterning, the substrate protection film 18 can be also similarly patterned as shown in FIGS. 9, 10A, and 10B. To avoid forming an unnecessary silicon pillar within the active region 13, an edge of the insulation film 19 that covers the STI 12 can be positioned at slightly outside of an outer circumference of the active region 13.

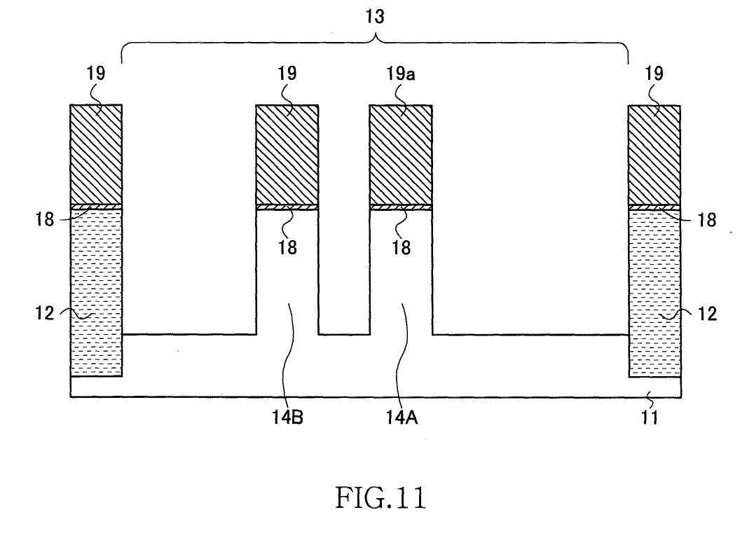

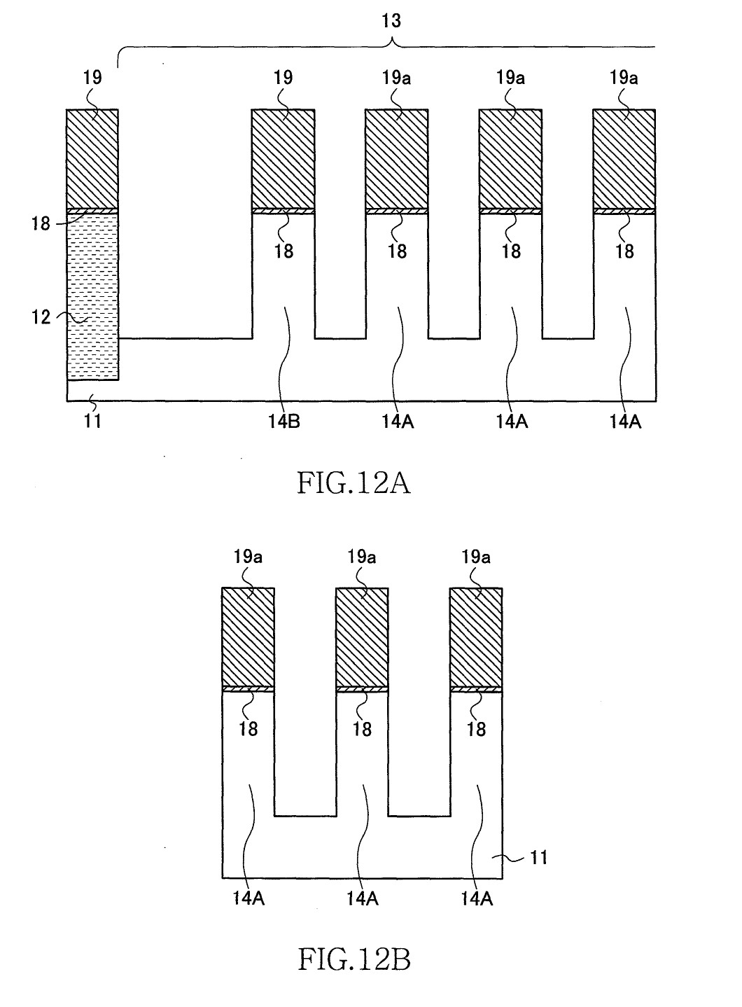

An exposed surface of the active region 13 is dug by dry etching using the mask pattern which is patterned in this way (FIGS. 11, 12A, and 12B). By this etching process, the first and second silicon pillars 14A and 14B substantially perpendicular to the main surface of the silicon substrate 11 are formed. The remaining part of the insulation film 19 becomes a cap insulation film that covers upper sides of silicon pillars.

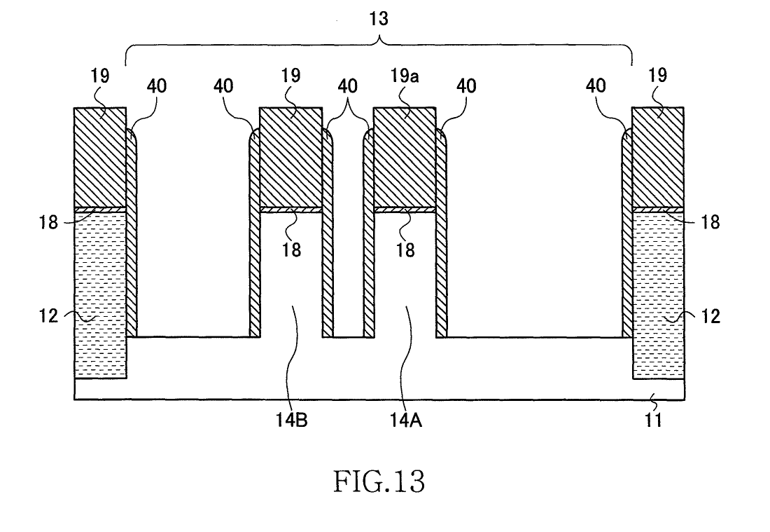

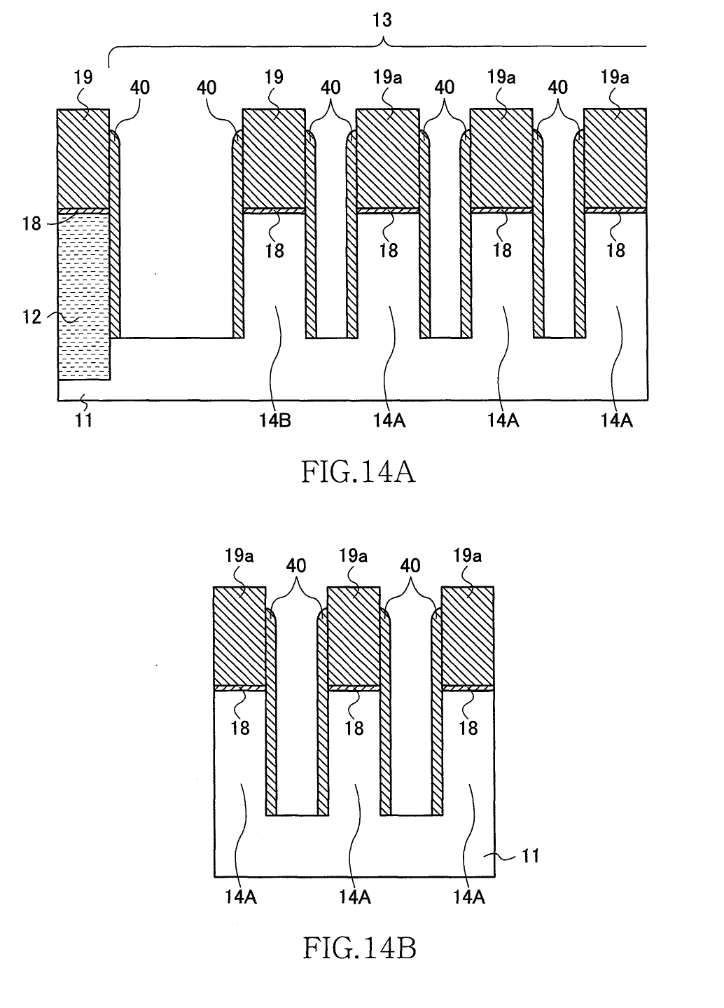

A sidewall dielectric film 40 is then formed on side surfaces of the first and second silicon pillars 14A and 14B (FIGS. 13, 14A, 14B). The sidewall dielectric film 40 is formed by forming a silicon nitride film, after protecting an exposed surface of the active region 13 by thermal oxidation, while leaving the cap insulation film 19, and by further etching back this silicon nitride film. As a result, an outer circumference surface of the active region 13 (an inner circumference surface of the STI 12) and side surfaces of the first and second silicon pillars 14A and 14B are covered with the sidewall dielectric film 40.

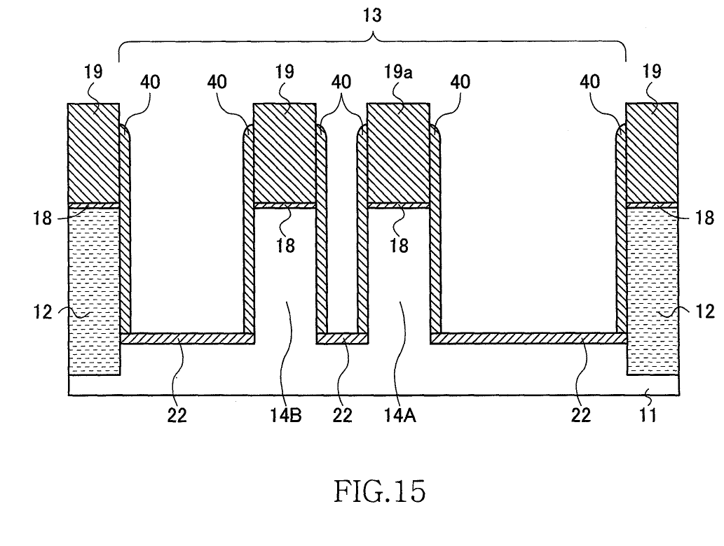

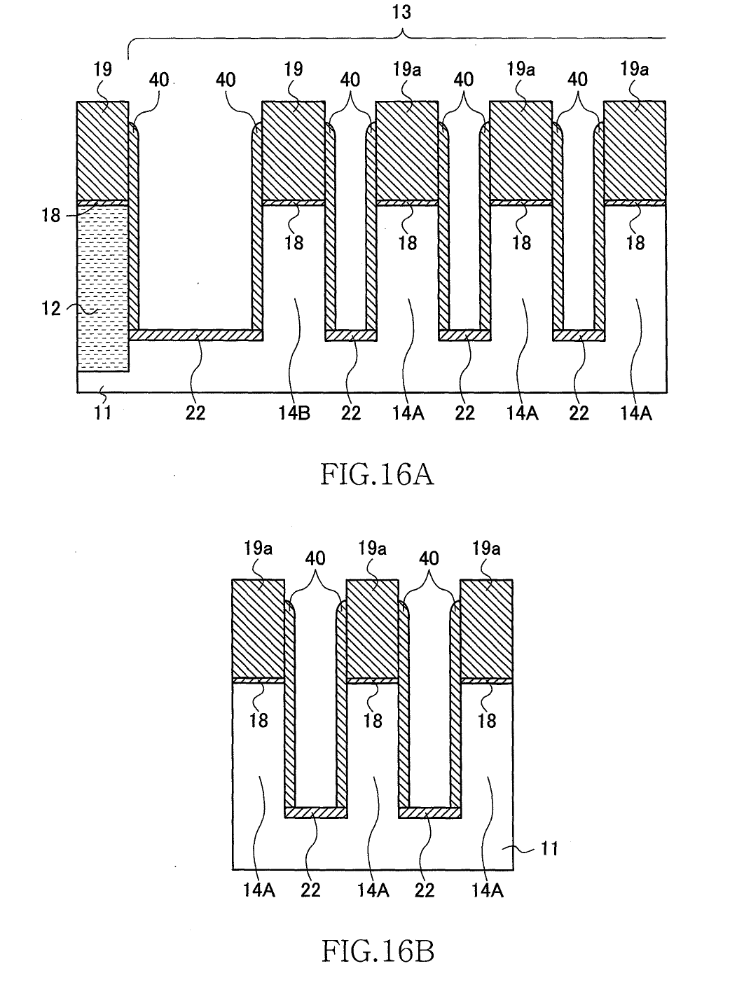

A silicon oxide film 22 is then formed by thermal oxidation on the exposed surface of the active region 13 (that is, a bottom surface of the active region 13) (FIGS. 15, 16A, and 16B). In this case, upper surfaces and side surfaces of the first and second silicon pillars 14A and 14B are covered with the cap insulation film 19 and the sidewall dielectric film 40, respectively, and therefore are not thermally oxidized. Although not particularly limited thereto, the film thickness of the silicon oxide film 22 is preferably about 30 nm.

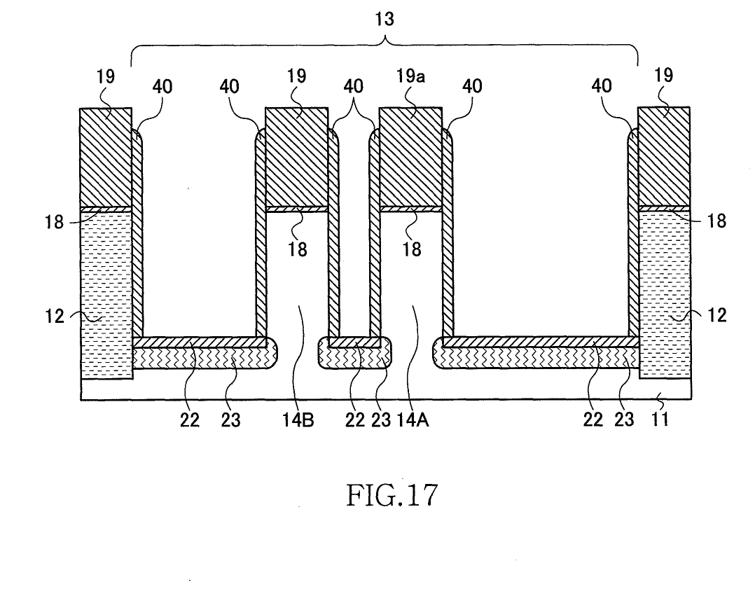

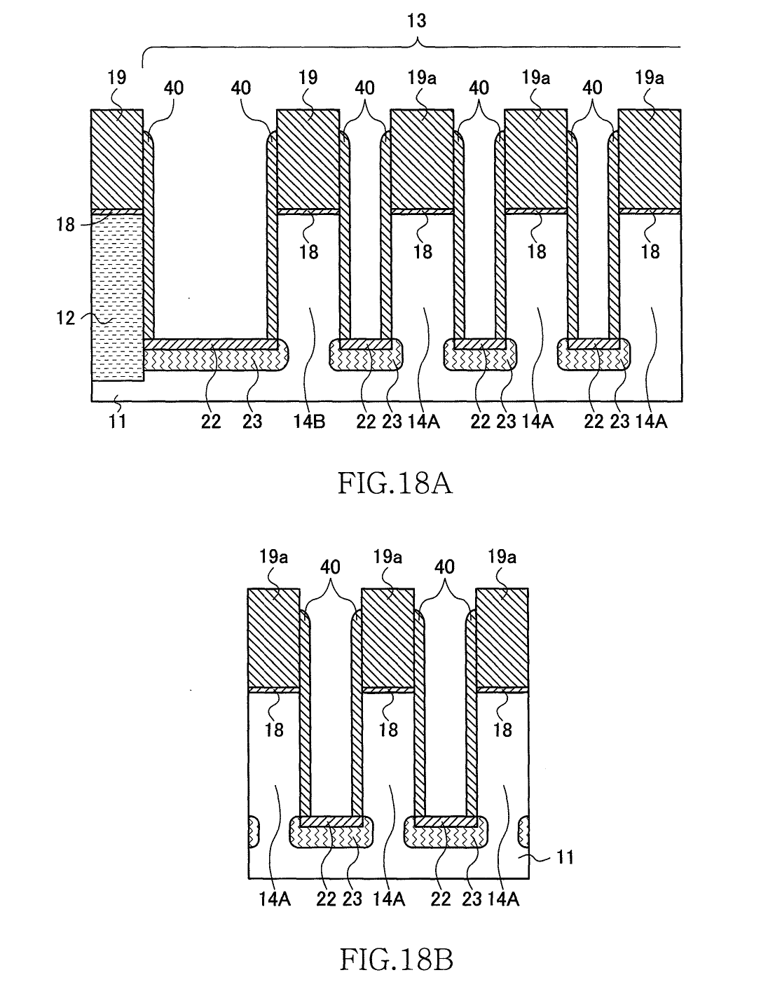

The second diffusion layer 23 is then formed at the lower parts of the first and second silicon pillars 14A and 14B (FIGS. 17, 18A, and 18B). The second diffusion layer 23 is formed by ion implanting an impurity having a conductivity type opposite to that of an impurity in the silicon substrate 11 via the silicon oxide film 22 formed on the surface of the active region 13.

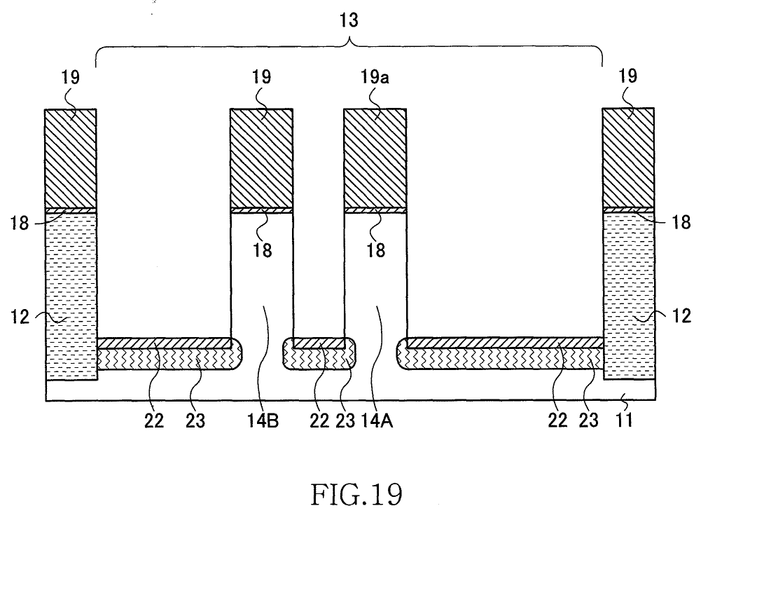

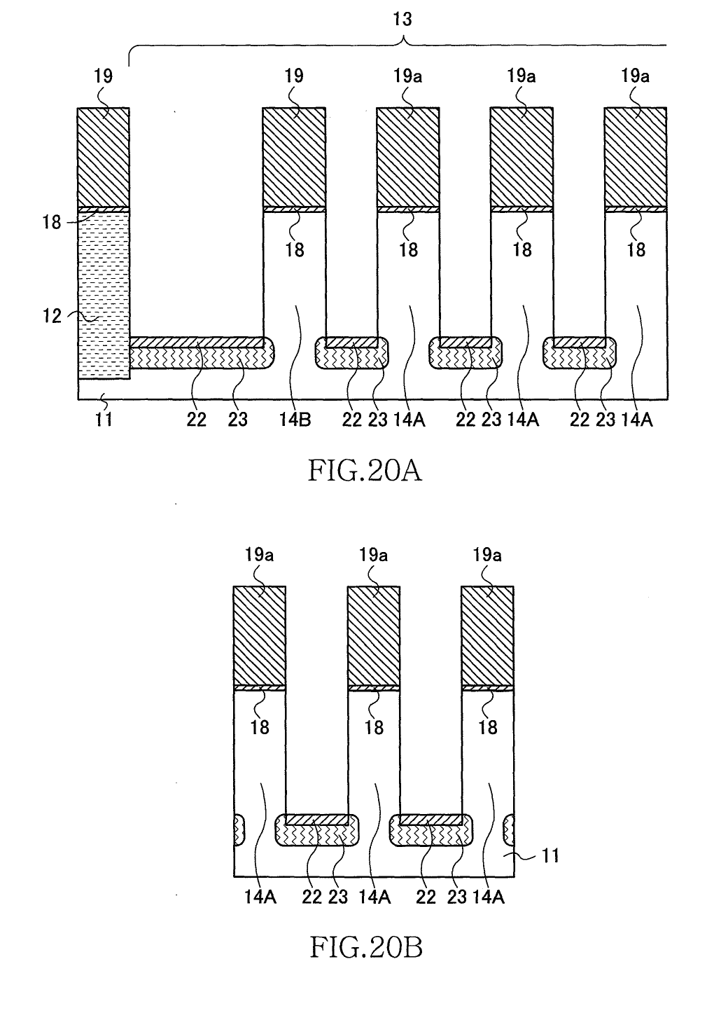

The sidewall dielectric film 40 is then removed by wet etching (FIGS. 19, 20A, and 20B). As a result, side surfaces of the silicon oxide film 22 formed on the bottom surface of the active region 13, and the side surfaces of the first and second silicon pillars 14A and 14B are exposed. The upper surfaces of the first and second silicon pillars 14A and 14B remain covered with the cap insulation film 19.

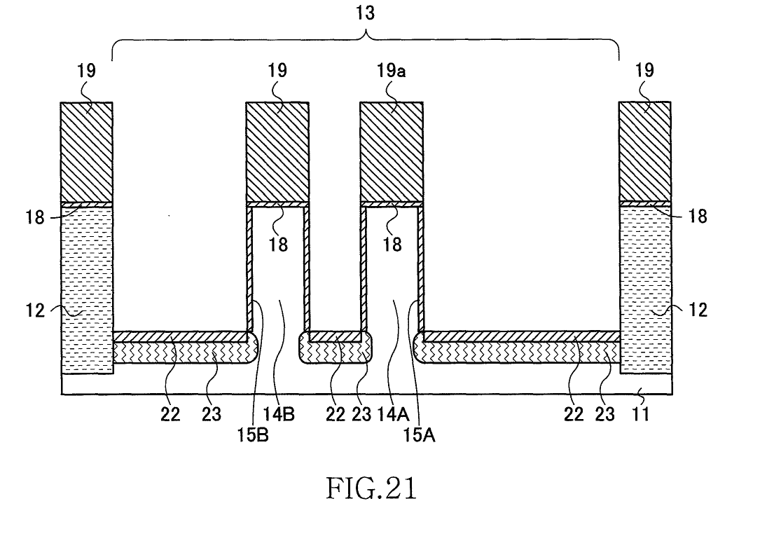

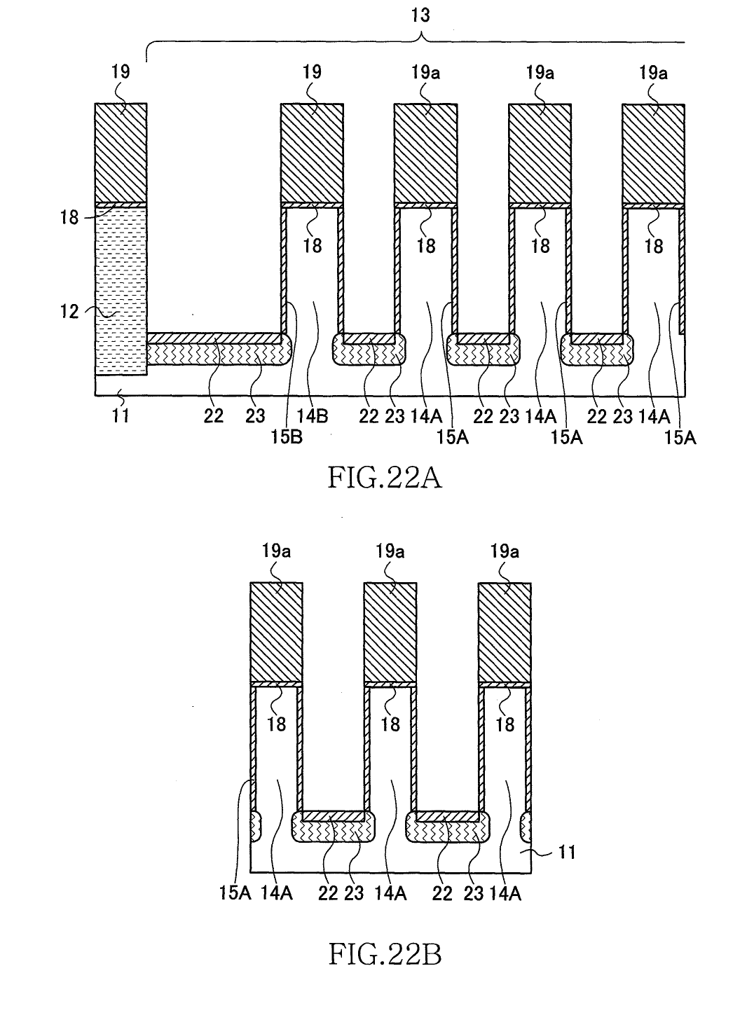

The gate dielectric films 15A and 15B are then formed simultaneously on the side surfaces of the first and second silicon pillars 14A and 14B, respectively (FIGS. 21, 22A, and 22B). The gate dielectric films 15A and 15B can be formed by thermal oxidation, and film thicknesses of these films are preferably about 5 nm, respectively.

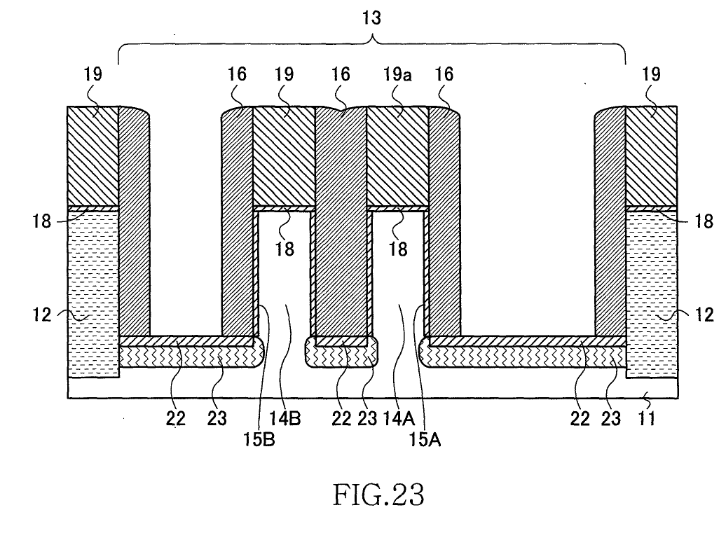

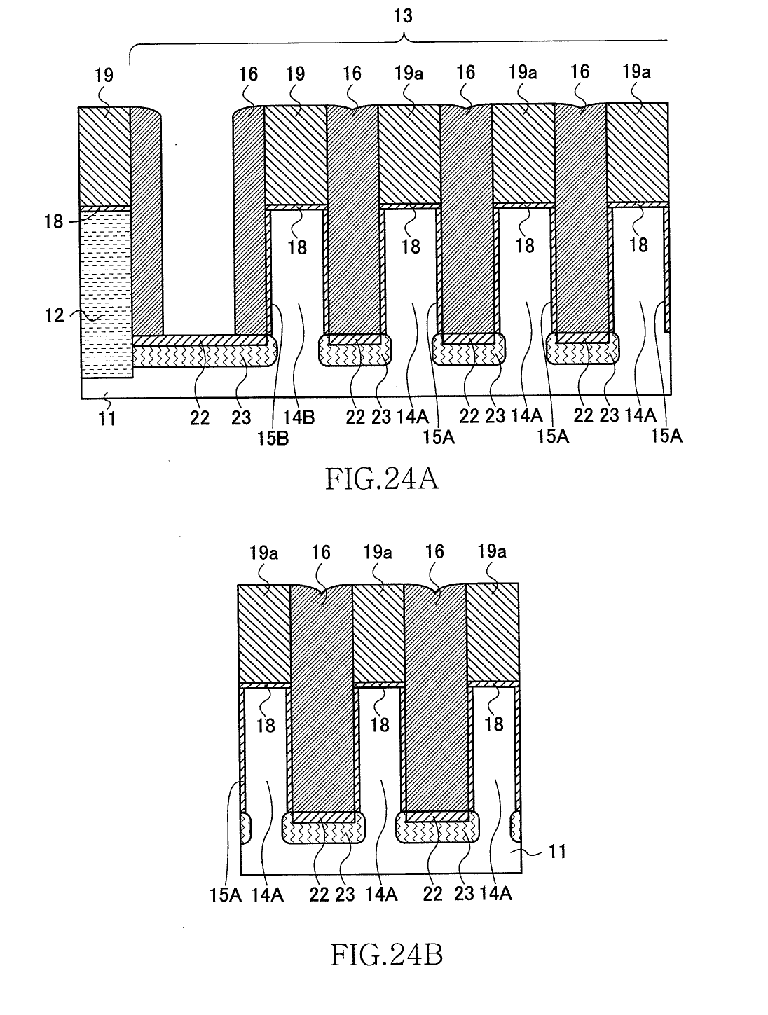

The gate electrode 16 made of a polycrystalline silicon film is then formed. The gate electrode 16 is formed by forming a polycrystalline silicon film having a film thickness of about 40 nm on the entire surface of the silicon substrate 11 by the CVD method, and thereafter by etching back the polycrystalline silicon film by anisotropic dry etching (FIGS. 23, 24A, and 24B). This etching back is performed by using a commercially available parallel-plane RIE (Reactive Ion Etching) apparatus, by introducing CH₂F₂ gas 40 sccm, O₂ gas 20 sccm, and Ar gas 250 sccm, until when surfaces of the cap insulation film 19 and the silicon oxide film 22 are exposed by RF400W at a pressure 120 mTorr. As a result, the side surfaces of the silicon pillars 14A and 14B are covered with the gate electrode 16. Although a polycrystalline silicon film remains on the side surface of the STI 12, this polycrystalline silicon film does not function as a gate electrode.

In the peripheral circuit, a distance between the first and second silicon pillars 14A and 14B is set smaller than two times of the film thickness of the gate electrode 16 as shown in FIG. 23. Therefore, the gate electrode 16 formed on the side surface of the first silicon pillar 14A and the gate electrode 16 formed on the side surface of the second silicon pillar 14B are integrated together in contact with each other at a gap portion between the first and second silicon pillars 14A and 14B. In the memory cell region, a distance between silicon pillars arranged in a row direction is also set smaller than two times of the film thickness of the gate electrode 16 as shown in FIG. 24A. Therefore, the gate electrodes 16 formed on side surfaces of these silicon pillars are integrated together in contact with each other at a gap portion between the silicon pillars, and constitute one gate electrode 16. On the other hand, as shown in FIG. 24B, a distance between silicon pillars arranged in a column direction is set slightly longer than the distance between the silicon pillars arranged in the row direction. Although FIG. 24B shows that the gate electrodes 16 formed on the side surfaces of the silicon pillars are integrated together in contact with each other, the gate electrodes 16 do not need to be integrated together in this process. Even when the gate electrodes 16 are integrated together, these gate electrodes 16 are isolated in a process described later.

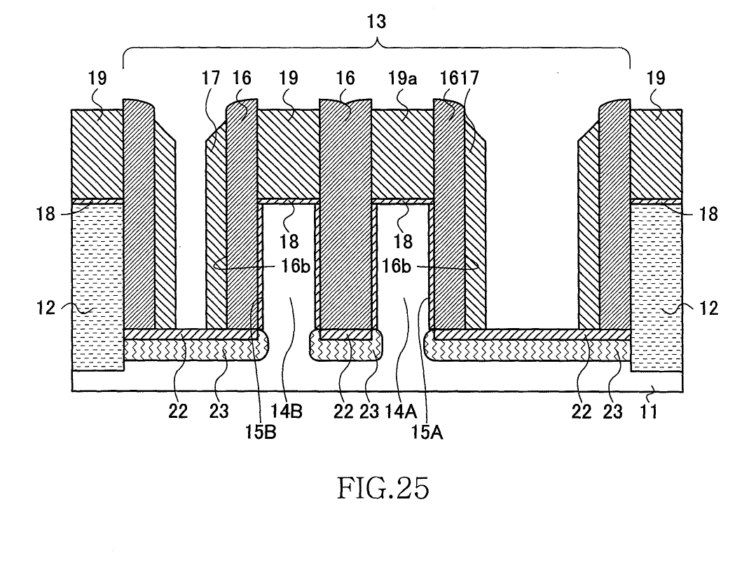

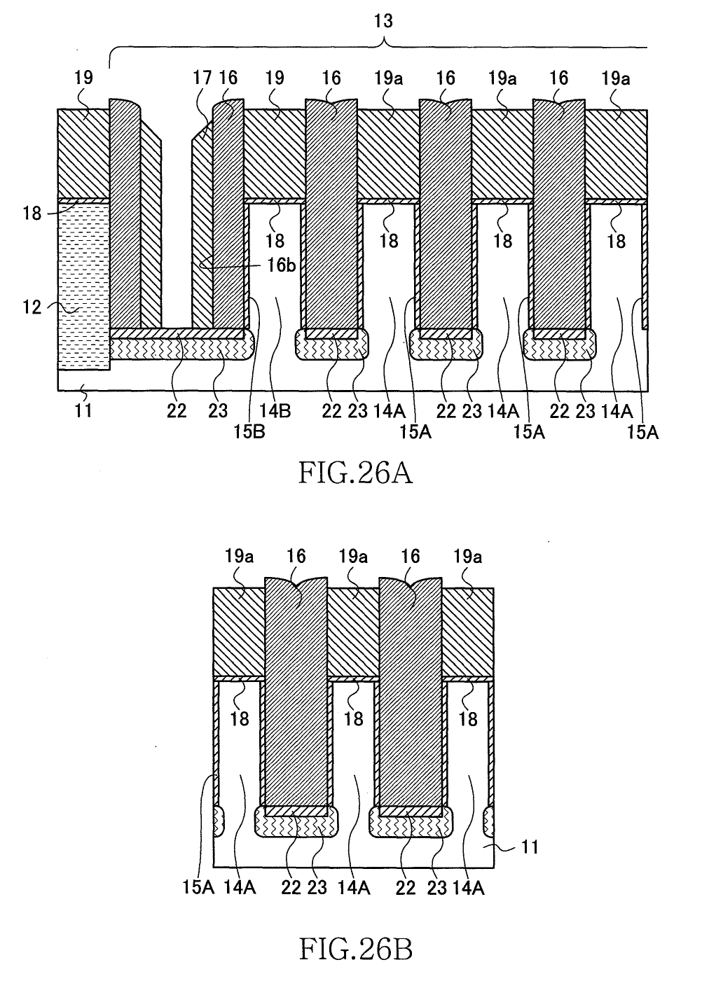

A silicon nitride film of a thickness about 20 nm is formed by the CVD method, and a nitride film is etched back by anisotropic dry etching thereby forming the gate-electrode protection film 17 made of the silicon nitride film (FIGS. 25, 26A, and 26B). The etching back is performed until when an upper surface of the gate electrode 16 is exposed. Because the cap insulation film 19 is also etched by this etching back as shown in each of the drawings, the cap insulation film 19 preferably has a large film thickness by taking into account an amount of this film etched by the etching back.

Up to the above process, the outer-circumference side surface 16b of the gate electrode 16 is covered with the gate-electrode protection film 17 made of a silicon nitride film. Therefore, at the time of etching back the gate electrode 16 in the next process, the gate-electrode protection film 17 becomes a barrier, and etching is not performed in a lateral direction.

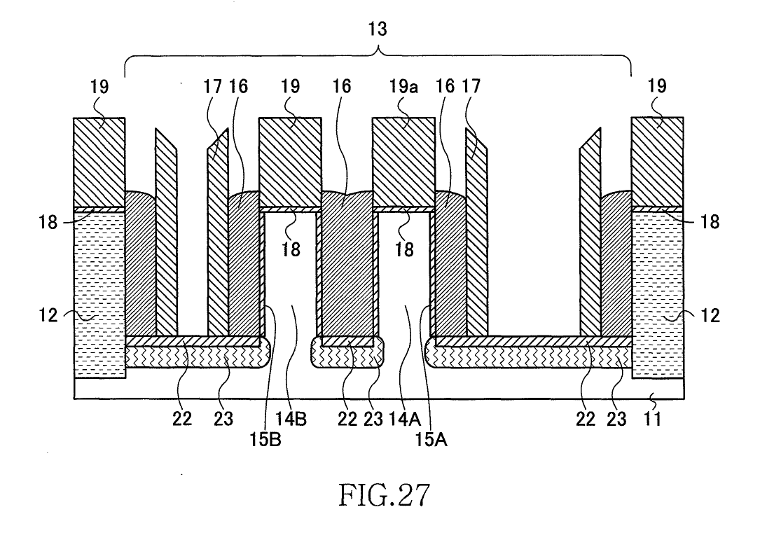

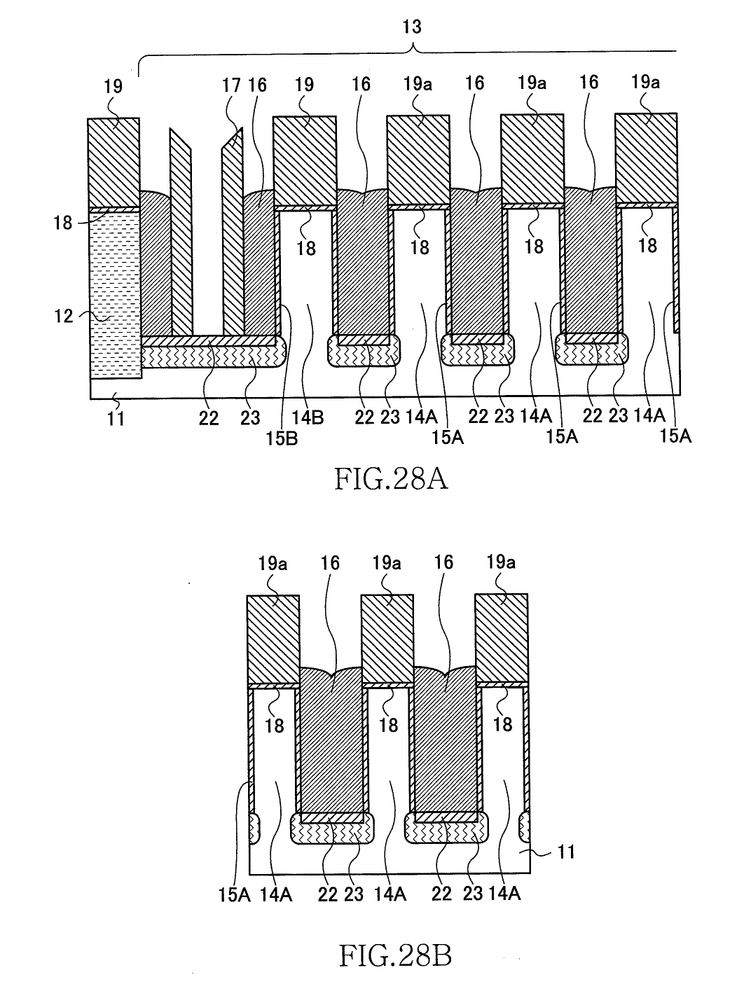

After the gate-electrode protection film 17 is formed, the gate electrode 16 is etched back next. Specifically, the anisotropic dry etching of the polycrystalline silicon film described above is performed again. As a result, as shown in FIGS. 27, 28A, and 28B, the upper surface position of the gate electrode 16 is lowered. An object of this processing is to reduce a floating capacitance between the first diffusion layer 20 formed in a later process and the gate electrode 16. Therefore, most preferably, a height of the upper surface position of the gate electrode 16 is set the same as a height of the upper surface position of the silicon pillars. However, by considering an error, a height about slightly higher than the upper surface position of the silicon pillars can be set in practice as a target as shown in each of the drawings.

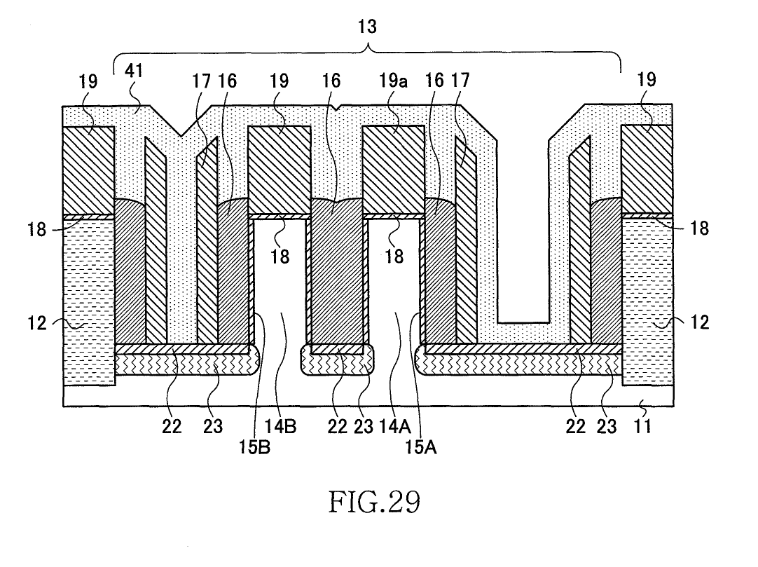

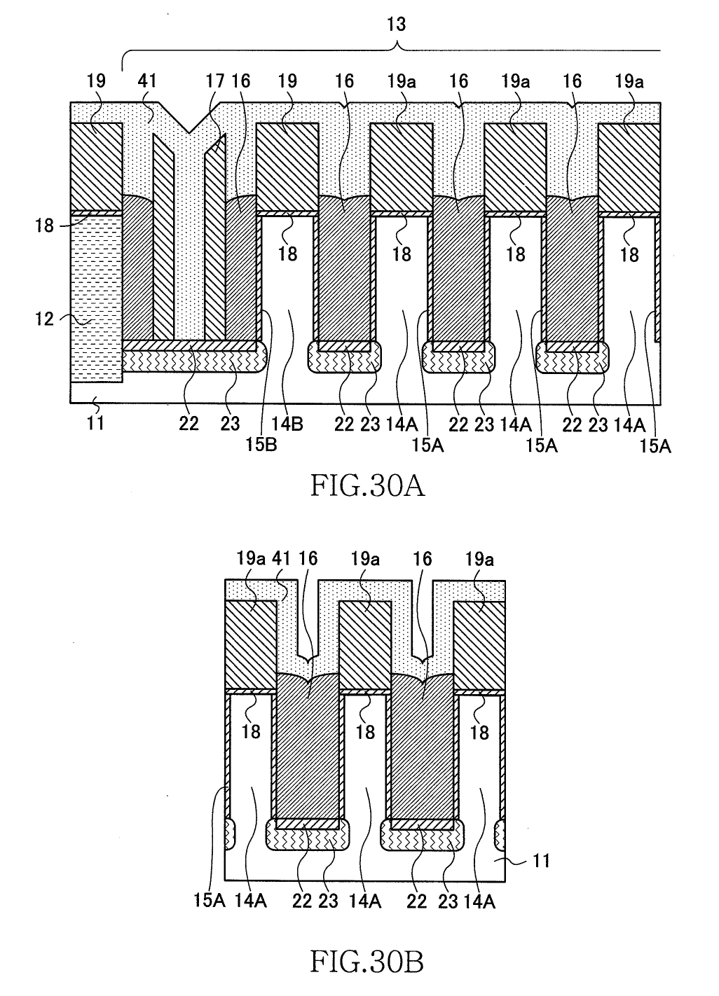

A process of isolating the gate electrodes 16 in a column direction is performed in the memory cell region. Specifically, by an LP-CVD (Low-Pressure Chemical-Vapor Deposition) method, a silicon oxide film 41 is formed on the entire surface of the silicon substrate 11 (FIGS. 29, 30A, and 30B). Preferably, the film thickness of the silicon oxide film 41 is about a thickness (for example, about 20 nm) at which an interval between the first silicon pillars 14A shown in FIG. 30B is not completely embedded with the silicon oxide film 41.

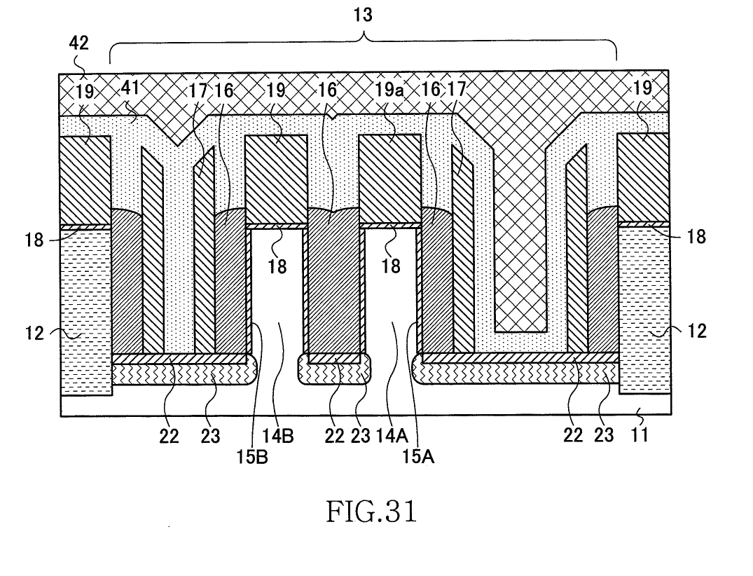

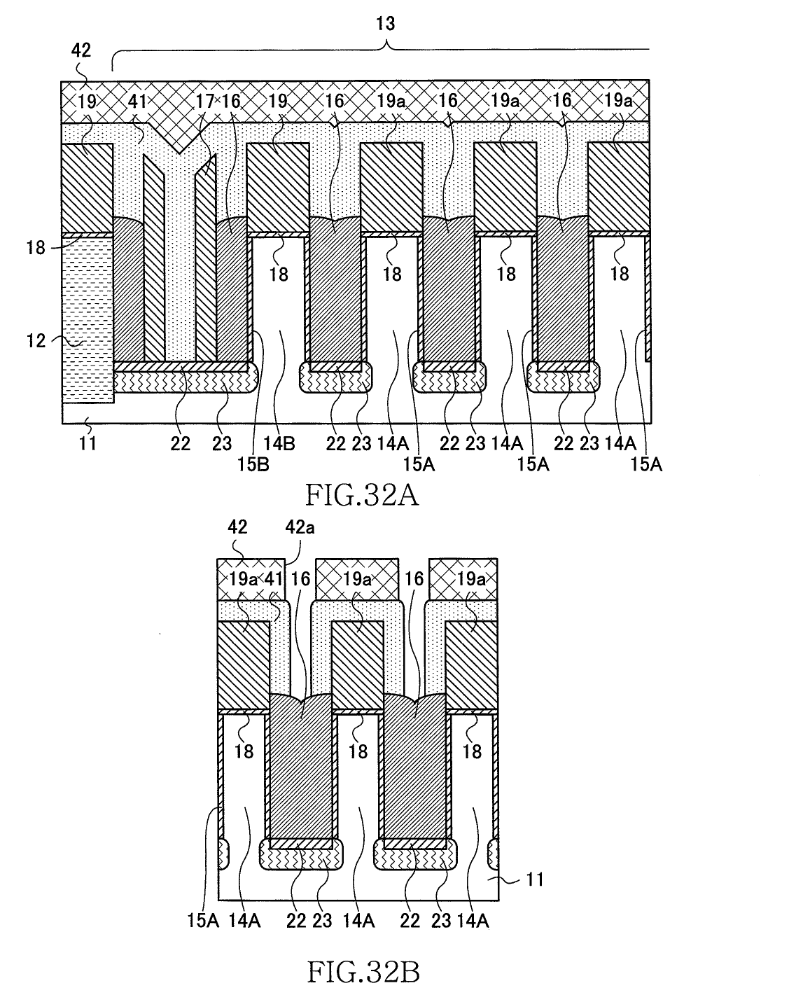

After the silicon oxide film 41 is formed, a photoresist 42 is coated on this. By performing an exposure using a mask pattern, an opening 42a is provided between the first silicon pillars 14A arranged in the column direction in the memory cell region as shown in FIG. 32B. Further, the silicon oxide film 41 within the opening 42a is removed by anisotropic dry etching (FIGS. 31, 32A, and 32B).

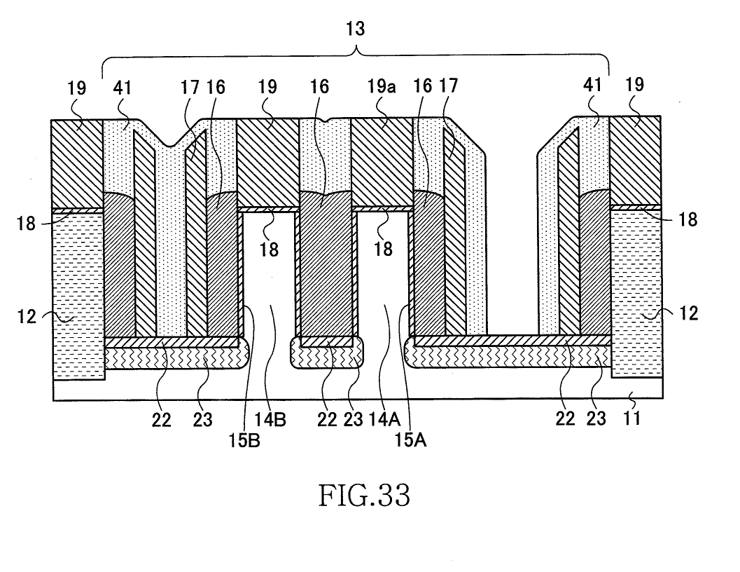

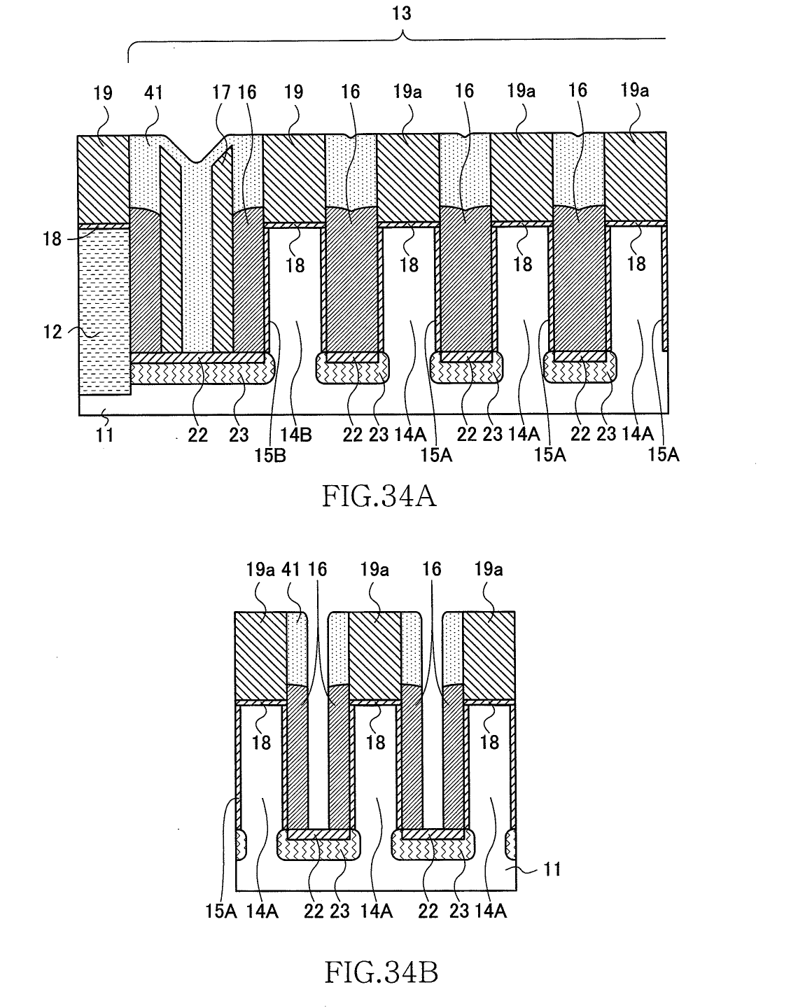

Next, the photoresist 42 is removed, and the gate electrode 16 is etched by performing the anisotropic dry etching using the silicon oxide film 41 as a mask (a word-line oxide film mask) (FIGS. 33, 34A, and 34B). By this etching, overetching is performed to some extent to securely isolate the gate electrodes 16 between the first silicon pillars 14A arranged in the column direction in the memory cell region. As shown in the drawings, the silicon oxide film 41 is also simultaneously etched to some extent.

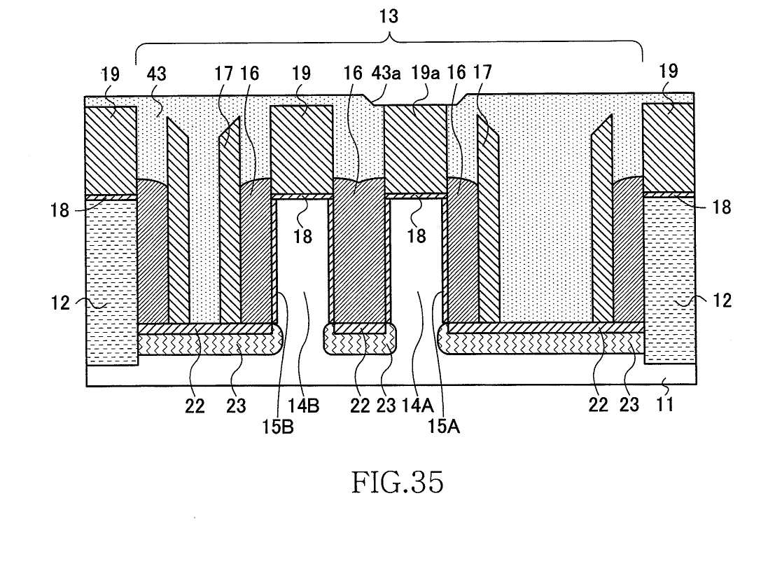

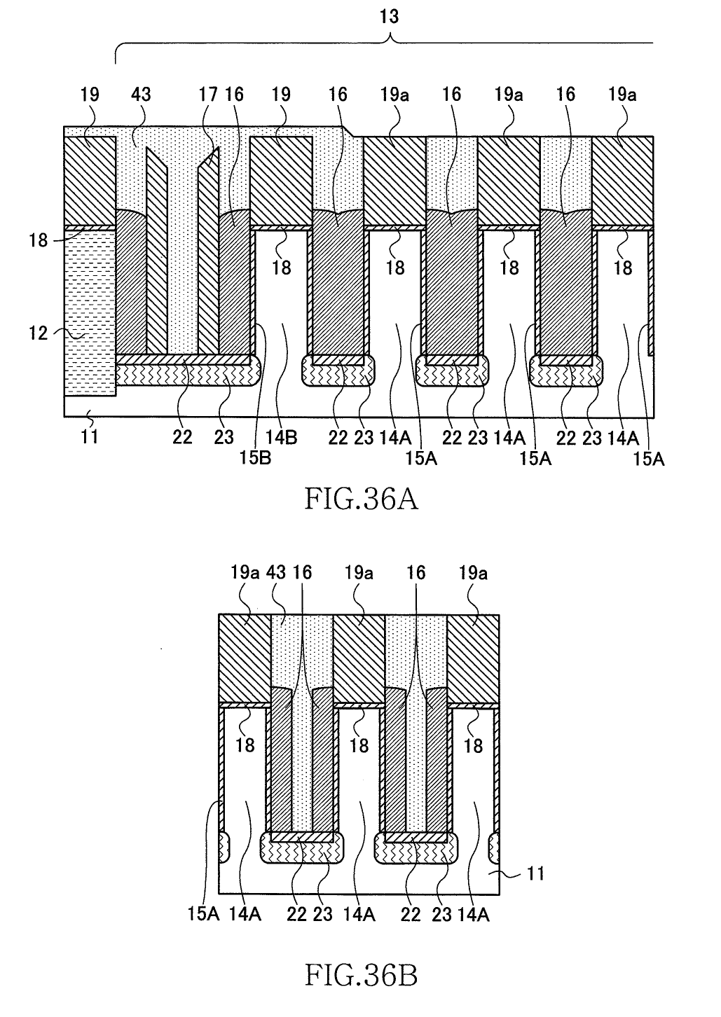

A silicon oxide film is then formed on the entire surface of the silicon substrate 11 by the HDP method, and the silicon oxide film is planarized by CMP using the cap insulation film 19 as a stopper. Thereafter, a plasma oxide film is formed in a thickness of by about 10 nm on the entire surface of the silicon substrate 11, thereby forming an interlayer dielectric film 43 (FIGS. 35, 36A, and 36B). An opening 43a exposing the cap insulation film 19a is formed on the interlayer dielectric film 43 as shown in each of the drawings. In forming the opening 43a, anisotropic dry etching using a lithography mask is used.

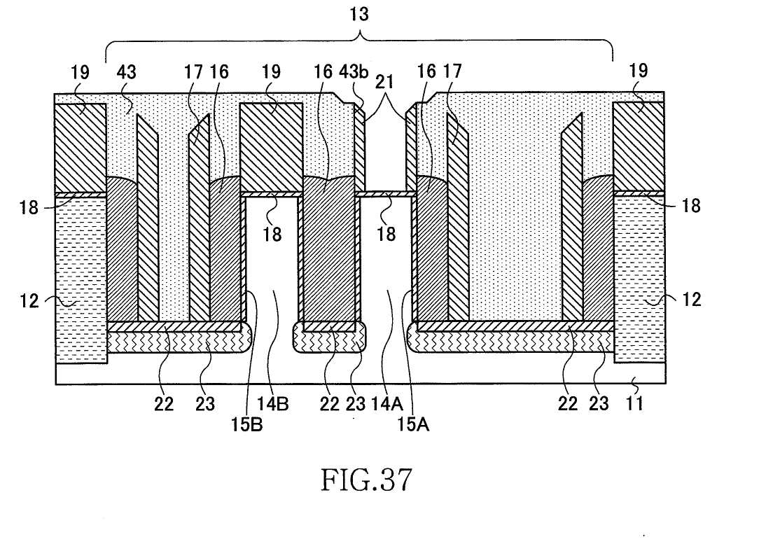

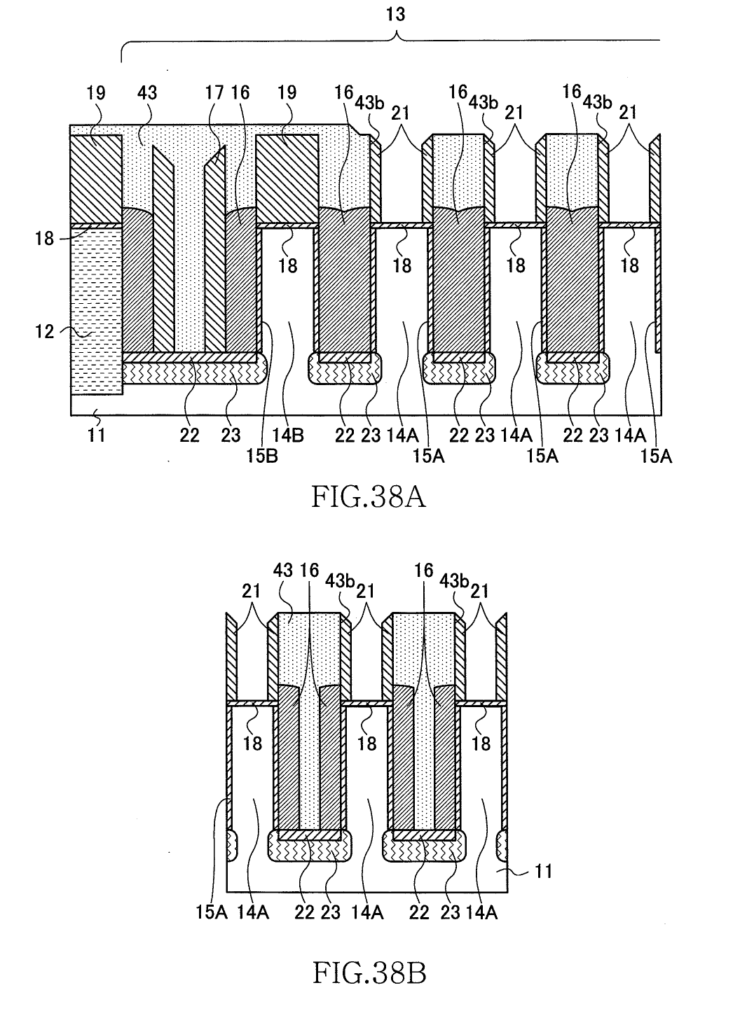

The cap insulation film 19a is then removed by thermal phosphoric acid, thereby exposing the substrate protection film 18 at the upper part of the first silicon pillar 14A. At inside of a through hole 43b formed by removing the cap insulation film 19a, a sidewall nitride film 21 is formed by the CVD method and by anisotropic dry etching (FIGS. 37, 38A, and 38B). The sidewall nitride film 21 is formed to insulate a conductive material (the first diffusion layer 20) filled within the through hole 43b from the gate electrode 16 in a process described later.

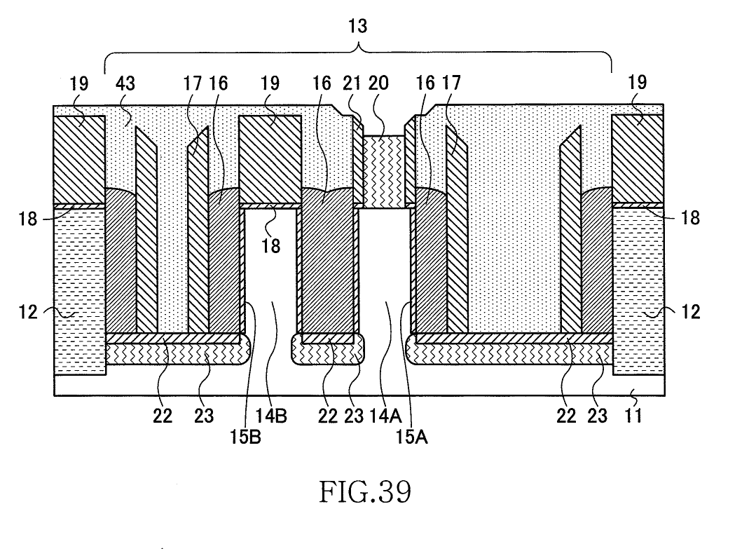

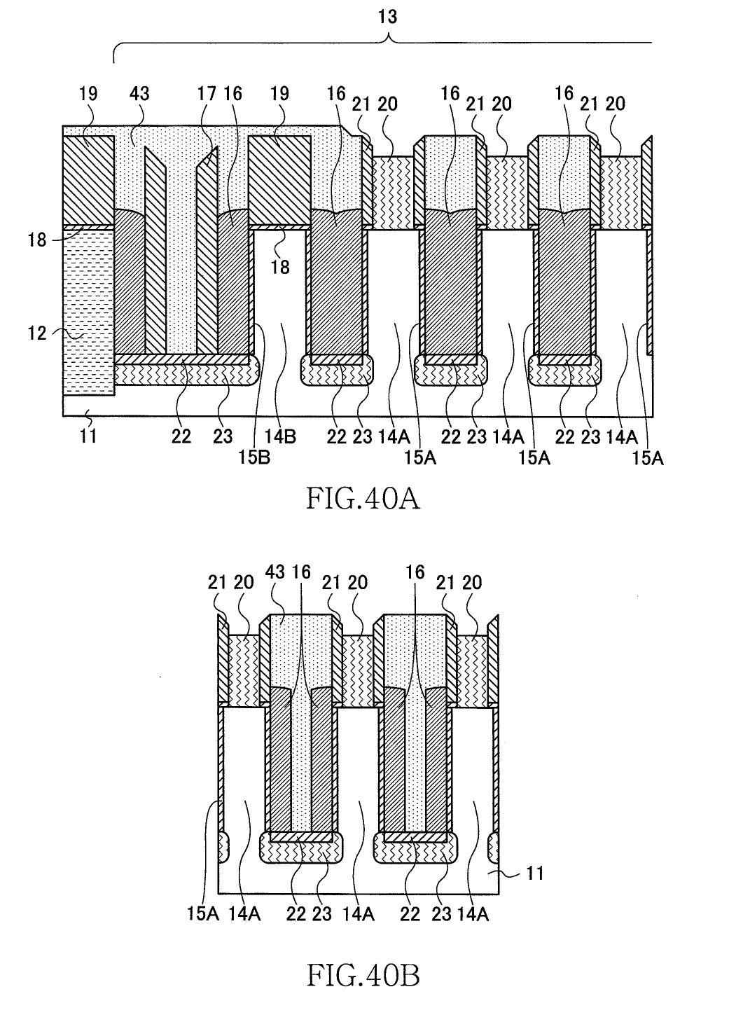

The substrate protection film 18 on a bottom surface of the through hole 43b is then removed by rare hydrofluoric acid, and thereafter silicon is selectively epitaxially grown within the through hole 43b. An impurity having a conductivity type opposite to that of an impurity in the silicon substrate 11 is ion implanted, and an activation RTA is performed, thereby forming the first diffusion layer 20 (FIGS. 39, 40A, and 40B).

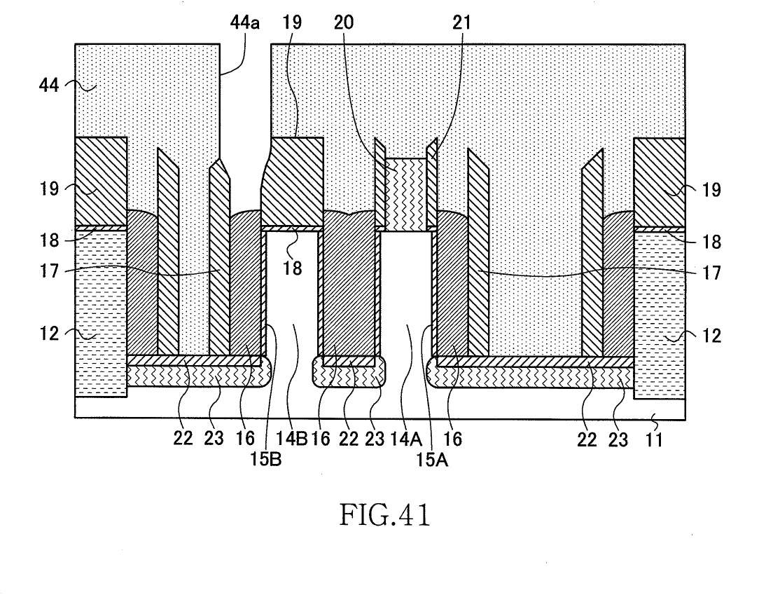

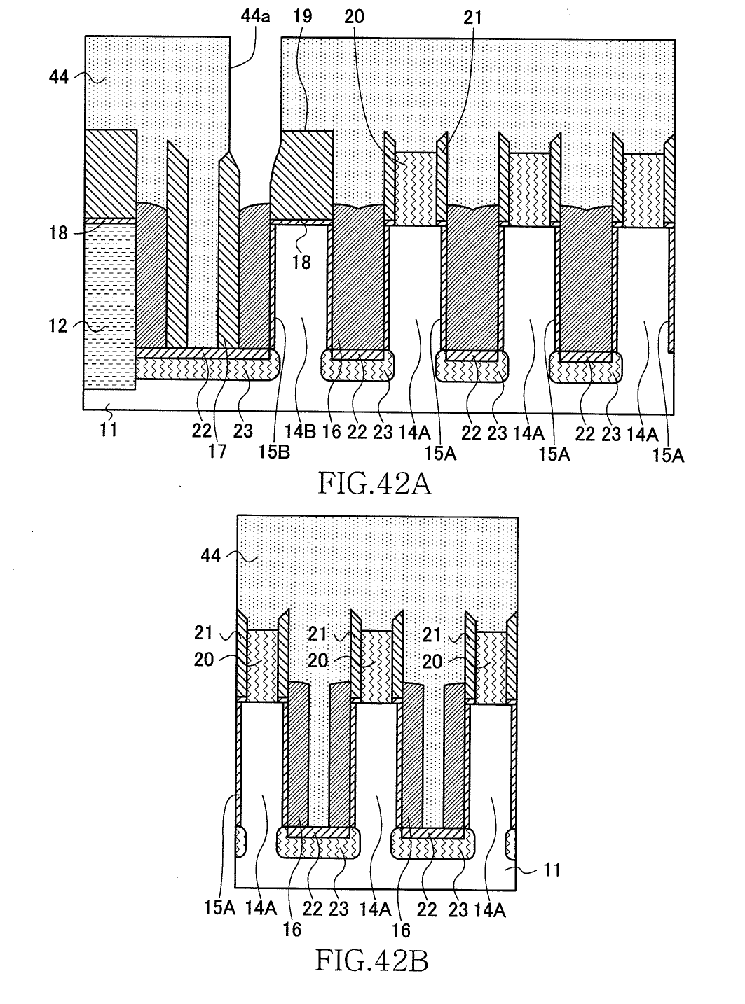

A silicon oxide film is then deposited on the entire surface of the silicon substrate 11 by the HDP method, and the surface is planarized by CMP, thereby forming an interlayer dielectric film 44 (FIGS. 41, 42A, and 42B). A through hole 44a (a contact hole) is provided on the interlayer dielectric film 44 using a lithography mask and by anisotropic dry etching. The through hole 44a is used to embed the gate contact plug GC, and is provided above the side surface of the second silicon pillar 14B and at a position where the gate electrode 16 and the gate-electrode protection film 17 are exposed. The anisotropic dry etching to provide the through hole 44a is performed at a pressure 20 mTorr by introducing C₄F₆ gas, O₂ gas, and Ar gas in a total flow amount 250 sccm. At the time of performing this anisotropic dry etching, the cap insulation film 19 on the second silicon pillar 14B and the gate-electrode protection film 17 function as a contact guide to the gate electrode 16. Therefore, occurrence of a positional deviation between the through hole 44a and the gate electrode 16 is prevented.

A through hole is then provided on the interlayer dielectric film 44 to embed the first and second diffusion-layer contact plugs DC1 and DC2, and tungsten is embedded into each through hole including the through hole 44a, thereby forming the gate contact plug GC and the first and second diffusion-layer contact plugs DC1 and DC2 as shown in FIG. 1A, FIG. 2 and FIG. 3. Thereafter, a wiring layer including the word line WL and the bit line BL and the capacitor Cp are formed on an upper layer, thereby completing the semiconductor device 10.

It is apparent that the present invention is not limited to the above embodiments, but may be modified and changed without departing from the scope and spirit of the invention.

For example, although the gate electrode 16 is configured by a polycrystalline silicon film in the above embodiments, the gate electrode 16 can be a laminated film of titanium nitride and tungsten, thereby reducing a word line resistance. A process of performing etching of the gate electrode 16 in the manufacturing method of the semiconductor device 10 in this case is explained in detail in comparison with the method in the above embodiments.

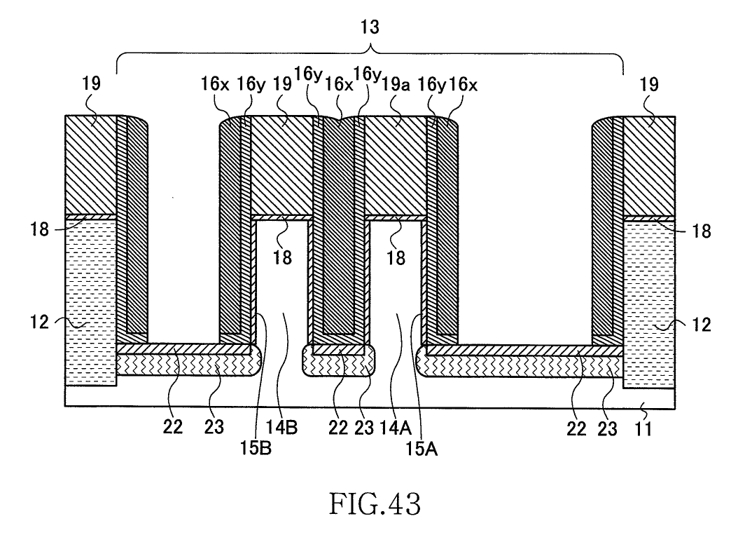

FIG. 43 to FIG. 48 are process diagrams for explaining the manufacturing method of the semiconductor device 10 according to a modification. Each of FIG. 43 to FIG. 48 corresponds to FIG. 23, FIG. 24, FIG. 27, FIG. 28, FIG. 33, and FIG. 34, respectively.

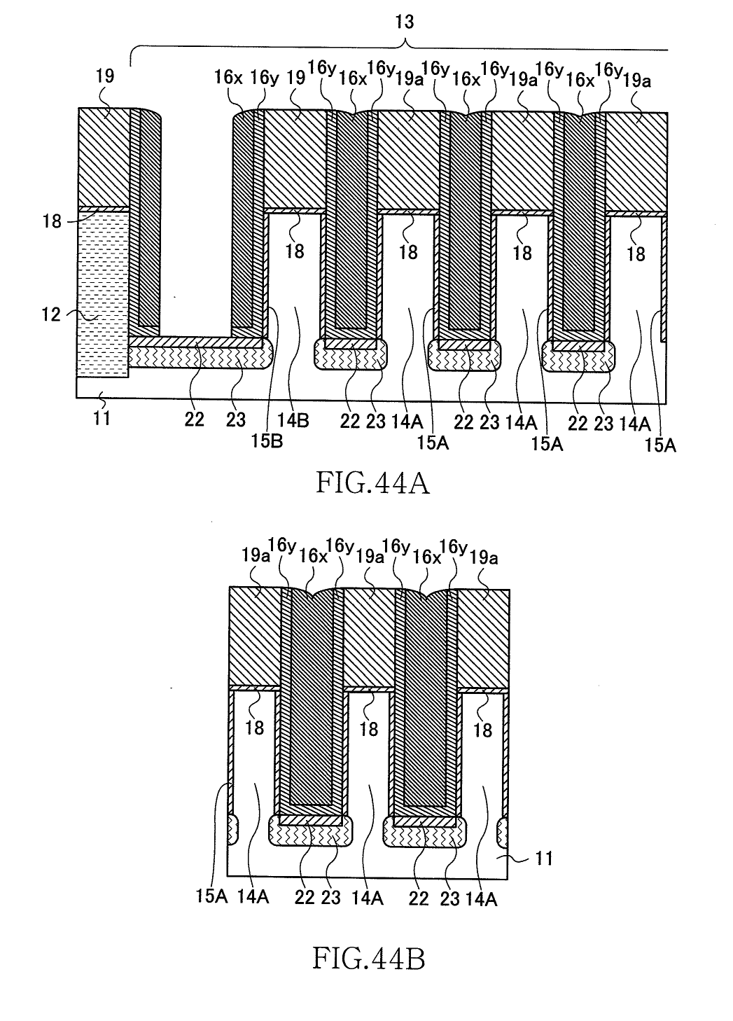

First, in a process (a film formation process of the gate electrode 16) shown in FIGS. 43, 44A, and 44B, the gate electrode 16 is formed by forming a film of titanium nitride 16y in a thickness of about 5 nm, and forming a film of tungsten 16x in a thickness of about 35 nm by the CVD method. Thereafter, formed films are etched until when the cap insulation film 19 and the silicon oxide film 22 are exposed. Specifically, the tungsten 16x is anisotropically etched back first, and thereafter the titanium nitride 16y is isotropically etched back. To etch back the tungsten 16x, a commercially available etching apparatus of an ICP plasma source is used, and CF₄ gas 80 sccm, N₂ gas 50 sccm, and O₂ gas 20 sccm are introduced, at 1000 W for a source and 100 W for a bias, at a pressure 10 mTorr. To etch back the titanium nitride 16y, a commercially available etching apparatus of an ICP plasma source is used, and Cl₂ gas 100 sccm, BCl₂ gas 20 sccm, and Ar gas 50 sccm are introduced, at 1000 W for a source and 10 W for a bias, at a pressure 10 mTorr.

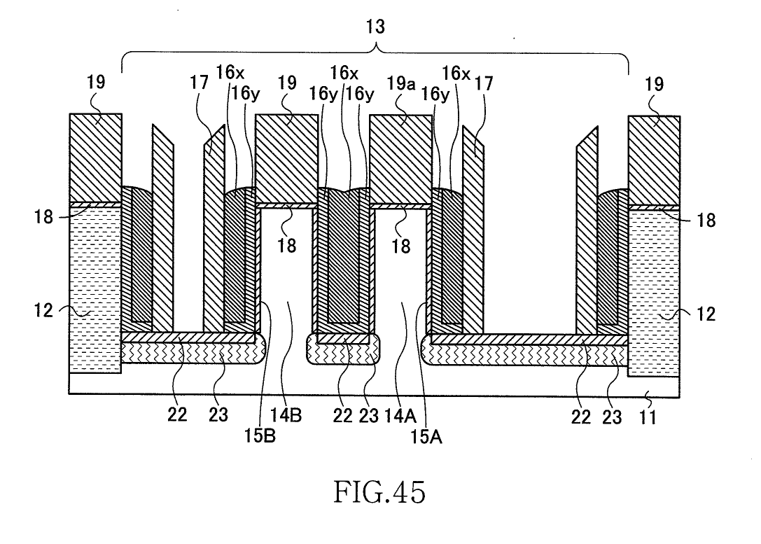

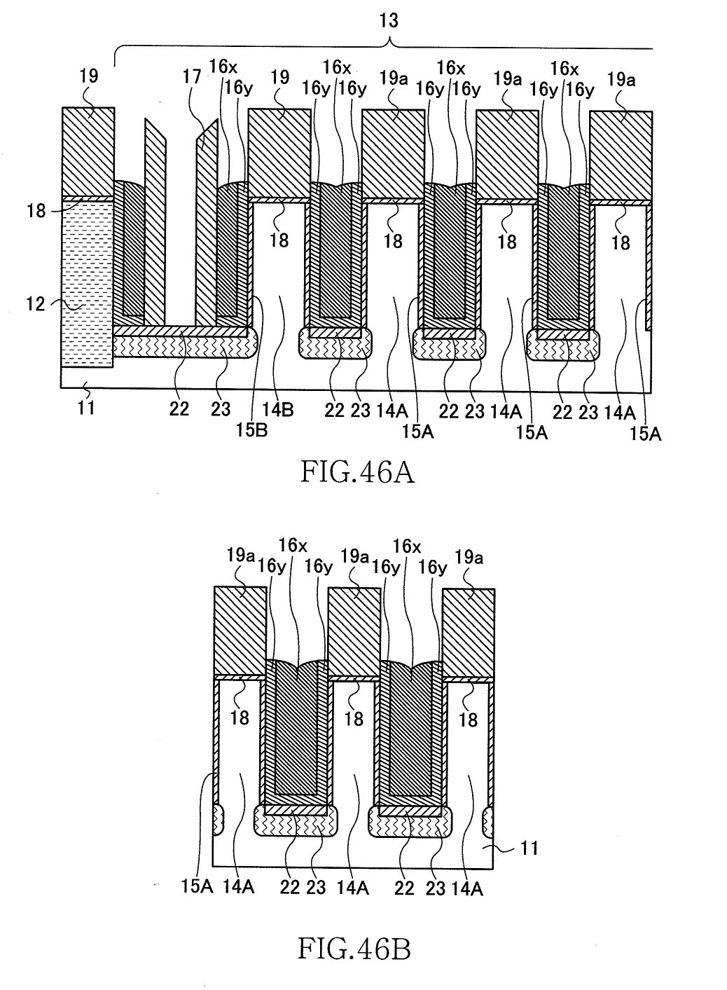

Next, in a process shown in FIGS. 45, 46A, and 46B (a process of etching back the gate electrode 16 after forming the gate-electrode protection film 17), an upper surface position of the gate electrode 16 is lowered by isotropically etching the tungsten 16x and the titanium nitride 16y. Isotropic etching is used in this case, because an etching rate of tungsten and an etching rate of the silicon oxide film 22 are almost the same when tungsten is etched anisotropically. When performing isotropic etching, the film thickness of the gate electrode 16 in a lateral direction is maintained because the gate-electrode protection film 17 is present. A specific etching condition for the tungsten 16x is that a bias is changed to 10 W in the condition described above, and the etching condition for the titanium nitride 16y is the same as that described above.

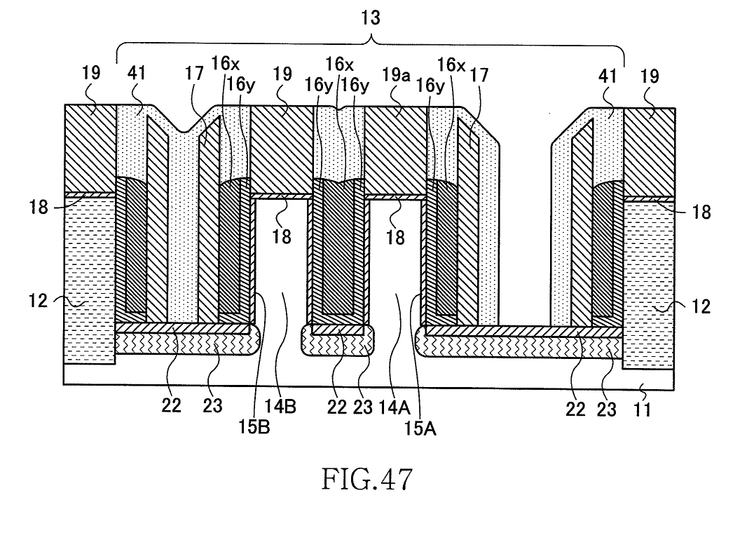

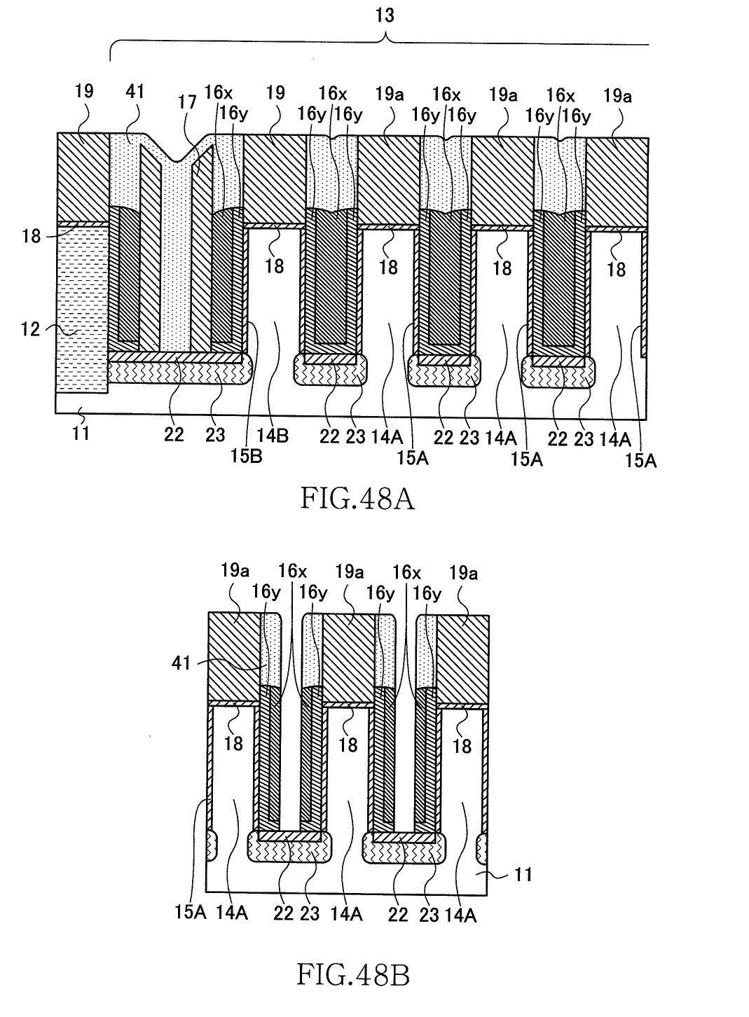

Next, in a process (a process of etching the gate electrode 16 by using a word-line oxide film mask) shown in FIGS. 47, 48A, and 48B, first, the tungsten 16x is anisotropically etched back, and thereafter the titanium nitride 16y is isotropically etched back, thereby isolating the gate electrodes 16 between the first silicon pillars 14A arranged in a column direction in the memory cell region. The specific etching condition is as described above.

Besides, while the semiconductor device 10 according to the above embodiments has been explained as a DRAM, the present invention is also applicable to other types of semiconductor devices such as a PRAM (Phase change Random Access Memory).

In addition, while not specifically claimed in the claim section, the applicant reserves the right to include in the claim section of the application at any appropriate time the following methods:

A1. A manufacturing method of a semiconductor device comprising:

forming a gate electrode material on a main surface of a silicon substrate having at least one silicon pillar;

etching back the gate electrode material so as to leave the gate electrode material on a side surface of the silicon pillar;

forming a gate-electrode protection film that covers the gate electrode material;

etching back the gate-electrode protection film so as to leave the gate-electrode protection film on a side surface of the gate electrode material;

etching back the gate electrode material after the etch back of the gate-electrode protection film to lower an upper surface position of the gate electrode material;

forming an interlayer insulating film that covers the gate electrode material and the gate-electrode protection film;

forming a contact hole in the interlayer insulating film that expose a part of the gate electrode material and the gate-electrode protection film; and

forming a contact plug within the contact hole.

A2. The manufacturing method of a semiconductor device according to A1, wherein the at least one silicon pillar comprises a first silicon pillar and a second silicon pillar, the method further comprising:

forming a first diffusion layer and a second diffusion layer at an upper part and a lower part of the first silicon pillar, respectively; and

forming a first contact plug and a second contact plug in contact with the first and second diffusion layers, respectively,

wherein the contact hole is formed in the interlayer insulating film exposing a part of the upper surface of a portion of the gate electrode material that surrounds the second silicon pillar.

A3. The manufacturing method of a semiconductor device according to A1, wherein the at least one silicon pillar comprises a plurality of first silicon pillars and at least one second silicon pillar, the method further comprising:

forming a plurality of first diffusion layers each of which is positioned at an upper part of an associated one of the first silicon pillars;

forming a plurality of second diffusion layers each of which is positioned within the semiconductor substrate at a lower part of an associated one of the first silicon pillars; and

forming a plurality of first contact plugs each of which is in contact with an associated one of the first diffusion layers,

wherein the contact hole is formed in the interlayer insulating film exposing a part of the upper surface of a portion of the gate electrode material that surrounds the second silicon pillar.

A4. The manufacturing method of a semiconductor device according to A1, wherein the gate electrode comprises polycrystalline silicon.

A5. The manufacturing method of a semiconductor device according to A1, wherein the gate electrode material is a laminated material comprising titanium nitride and tungsten.

What is claimed is:

1. A semiconductor device comprising:
a semiconductor substrate having a main surface;
at least one silicon pillar having a side surface substantially perpendicular to the main surface of the semiconductor substrate;
a gate dielectric film that covers the side surface of the silicon pillar;
a gate electrode having an inner-circumference side surface and an outer-circumference side surface which are substantially perpendicular to the main surface of the semiconductor substrate, the gate electrode covering the silicon pillar such that the inner-circumference side surface of the gate electrode and the side surface of the silicon pillar face each other via the gate dielectric film;
a gate-electrode protection film that covers at least a part of the outer-circumference side surface of the gate electrode;
an interlayer dielectric film provided above the gate electrode and the gate-electrode protection film, the interlayer dielectric film having a first contact hole; and
a gate contact plug embedded in the first contact hole, the gate contact plug being in contact with the gate electrode and the gate-electrode protection film.

2. The semiconductor device as claimed in claim 1, wherein
the at least one silicon pillar comprises a first silicon pillar and a second silicon pillar,
the gate dielectric film covers the side surface of each of the first and second silicon pillars,
the gate electrode covers the first and second silicon pillars such that the inner-circumference side surface faces the side surface of each of the first and second silicon pillars,
the gate contact plug is in contact with a part of an upper surface of a portion of the gate electrode that surrounds the second silicon pillar, and
the semiconductor device further comprises:
a first diffusion layer and a second diffusion layer formed at an upper part and a lower part of the first silicon pillar, respectively;
a first diffusion-layer contact plug that is embedded in a second contact hole provided on the interlayer dielectric film and is in contact with the first diffusion layer; and
a second diffusion-layer contact plug that is embedded in a third contact hole provided on the interlayer dielectric film and is in contact with the second diffusion layer.

3. The semiconductor device as claimed in claim 1, wherein
the at least one silicon pillar comprises a plurality of first silicon pillars and at least one second silicon pillar,
the gate dielectric film covers the side surface of each of the first and second silicon pillars,
the gate electrode covers the first and second silicon pillars such that the inner-circumference side surface faces the side surface of each of the first and second silicon pillars,
the gate contact plug is in contact with a part of an upper surface of a portion of the gate electrode that surrounds the second silicon pillar, and
the semiconductor device further comprises:
a plurality of first diffusion layers formed at an upper part of each of the first silicon pillars;
a second diffusion layer formed within the semiconductor substrate at a lower part of each of the first silicon pillars; and
a plurality of first diffusion-layer contact plugs each of which is embedded in an associated one of second contact holes provided on the interlayer dielectric film and is in contact with an associated one of the first diffusion layers.

4. The semiconductor device as claimed in claim 3, further comprising a second diffusion-layer contact plug that is embedded in a third contact hole provided on the interlayer dielectric film and is in contact with the second diffusion layer.

5. The semiconductor device as claimed in claim 1, wherein the gate electrode comprises a polycrystalline silicon.

6. The semiconductor device as claimed in claim 1, wherein the gate electrode is a laminated film comprising titanium nitride and tungsten.
